(19) United States
(12) Patent Application Publication
(10) Pub. No.: US 2026/0198009 A1
(43) Pub. Date: Jul. 9, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Gilsung Lee, Suwon-si (KR); Seung-Jun Lee, Suwon-si (KR); Youngwoo Kim, Suwon-si (KR); Tae Kyung Kim, Suwon-si (KR); Jae-Joo Shim, Suwon-si (KR)

(21) Appl. No.: 19/285,961

(22) Filed: Jul. 30, 2025

(30) Foreign Application Priority Data
Jan. 3, 2025 (KR) 10-2025-0000973

(51) Int. Cl. H10B 43/27; H01L 23/00; H01L 25/18; H10B 41/27; H10B 41/35; H10B 43/35; H10B 80/00; H10D 80/30

(52) U.S. Cl. CPC H10B 43/27; H10B 41/27; H10B 41/35; H10B 43/35; H10B 80/00; H10D 80/30; H10W 90/00; H10W 90/20; H10W 90/24; H10W 90/732; H10W 90/734; H10W 90/752; H10W 90/754; H10W 90/792

(57) ABSTRACT

An example semiconductor device includes a gate stacking structure, a channel structure, and a plurality of gate contacts. The gate stacking structure includes a plurality of interlayer insulation layers and a plurality of gate electrodes alternately stacked on each other. The channel structure extends through the gate stacking structure. Each gate contact passes through a portion of the gate stacking structure to be electrically connected to one gate electrode. The gate stacking structure includes a first stacking portion and a second stacking portion on the first stacking portion, and the first stacking portion includes at least one gate stacking portion. The plurality of gate contacts include a plurality of first contacts and a plurality of second contacts. The plurality of first contacts are electrically connected to a plurality of first electrodes, respectively. The plurality of second contacts are electrically connected to a plurality of second electrodes, respectively.

### CROSS-REFERENCE TO RELATED APPLICATION

This application claims priority to and the benefit of Korean Patent Application No. 10-2025-0000973 filed with the Korean Intellectual Property Office on Jan. 3, 2025, the entire contents of which are incorporated herein by reference.

### BACKGROUND

In an electronic system implementing a data storage, a semiconductor device capable of storing high-capacity data is in demand. Accordingly, a method for increasing a data storage capacity of a semiconductor device is being researched. For example, as one method for increasing the data storage capacity of a semiconductor device, a semiconductor device including three-dimensionally arranged memory cells instead of two-dimensionally arranged memory cells has been proposed.

### SUMMARY

The present disclosure relates to a semiconductor device capable of enhancing productivity and reliability and an electronic system including the same.

In general, according to some aspects, a semiconductor device includes a gate stacking structure, a channel structure, and a plurality of gate contacts. The gate stacking structure includes a plurality of interlayer insulation layers and a plurality of gate electrodes that are alternately stacked on each other. The channel structure extends through the gate stacking structure. Each gate contact of the plurality of gate contacts passes through a portion of the gate stacking structure, and is electrically connected to a respective gate electrode of the plurality of gate electrodes. The gate stacking structure includes a first stacking portion and a second stacking portion on the first stacking portion, and the first stacking portion includes at least one gate stacking portion. The plurality of gate contacts include a plurality of first contacts and a plurality of second contacts. The plurality of first contacts are electrically connected to a plurality of first electrodes, respectively, included in the first stacking portion. The plurality of second contacts are electrically connected to a plurality of second electrodes, respectively, included in the second stacking portion. The plurality of first contacts include a first shaped contact having a first shape. The first shaped contact includes an extension part passing through at least the second stacking portion, a connection part passing through a portion of the first stacking portion and electrically connected to a respective first electrode of the plurality of first electrodes, and an expanded part between the extension part and the connection part to be adjacent to a boundary of the at least one gate stacking portion. The expanded part protrudes from the connection part in a horizontal direction.

In general, according to some aspects, a semiconductor device includes a gate stacking structure, a channel structure, and a plurality of gate contacts. The gate stacking structure includes a plurality of interlayer insulation layers and a plurality of gate electrodes that are alternately stacked on each other. The channel structure extends through the gate stacking structure. Each gate contact of the plurality of gate contacts passes through a portion of the gate stacking structure, and is electrically connected to a respective gate electrode of the plurality of gate electrodes. The gate stacking structure includes a first stacking portion and a second stacking portion on the first stacking portion. The plurality of gate contacts include a plurality of first contacts and a plurality of second contacts. The plurality of first contacts are electrically connected to a plurality of first electrodes, respectively, included in the first stacking portion. The plurality of second contacts are electrically connected to a plurality of second electrodes, respectively, included in the second stacking portion. The plurality of first contacts include a first shaped contact having a first shape. The first shaped contact includes an extension part passing through at least the second stacking portion, a connection part passing through a portion of the first stacking portion and electrically connected to a respective first electrode of the plurality of first electrodes, and an expanded part passing through at least two gate electrodes of the plurality of gate electrodes or at least two interlayer insulation layers of the plurality of interlayer insulation layers. The expanded part protrudes from the connection part in a horizontal direction.

In general, according to some aspects, an electronic system includes a main substrate, a semiconductor device on the main substrate, and a controller electrically connected to the semiconductor device on the main substrate. The semiconductor device includes a gate stacking structure, a channel structure, and a plurality of gate contacts. The gate stacking structure includes a plurality of interlayer insulation layers and a plurality of gate electrodes that are stacked on each other. The channel structure extends through the gate stacking structure. Each gate contact of the plurality of gate contacts passes through a portion of the gate stacking structure, and is electrically connected to a respective gate electrode of the plurality of gate electrodes. The gate stacking structure includes a first stacking portion and a second stacking portion on the first stacking portion, and the first stacking portion includes at least one gate stacking portion. The plurality of gate contacts include a plurality of first contacts and a plurality of second contacts. The plurality of first contacts are electrically connected to a plurality of first electrodes, respectively, included in the first stacking portion. The plurality of second contacts are electrically connected to a plurality of second electrodes, respectively, included in the second stacking portion. The plurality of first contacts include a first shaped contact having a first shape. The first shaped contact includes an extension part passing through at least the second stacking portion, a connection part passing through a portion of the first stacking portion and electrically connected to a respective first electrode of the plurality of first electrodes, and an expanded part between the extension part and the connection part to be adjacent to a boundary of the at least one gate stacking portion. The expanded part protrudes from the connection part in a horizontal direction.

In general, according to some aspects, a first shaped contact includes an expanded part that is between an extension part in a first through portion and a connection part in a second through portion and protrudes in a horizontal direction. Accordingly, in a first etching process of forming the first through portion, etching may be stably stopped by an etch stopping pattern. The etch stopping pattern may be removed without remaining, and property deterioration that may occur when the etch stopping pattern remains may be prevented.

For example, the first through portion may be formed using a high aspect ratio contact etching process of forming a channel through portion, and a manufacturing process of the first through portion may be simplified and a number of a plurality of partial etching processes using a binary system in a second etching process of forming the second through portion may be reduced. The second through portion may have a relatively small length, and the second through portion may be stably formed at a desired position and a structural stability of the connection part in the second through portion may be improved to minimize distortion (e.g., bowing).

Thereby, productivity and reliability of a semiconductor device may be improved.

### BRIEF DESCRIPTION OF THE DRAWINGS

FIG. 1 is a partial cross-sectional view schematically illustrating an example of a semiconductor device.

FIG. 2 is an enlarged cross-sectional view illustrating an example of a channel structure that is included in the semiconductor device illustrated in FIG. 1.

FIG. 3 is a cross-sectional view illustrating an example of a connection region of a cell region that is included in the semiconductor device illustrated in FIG. 1.

FIG. 4 is a cross-sectional view illustrating an example of a thirty-sixth gate contact illustrated in FIG. 3.

FIG. 5 is a cross-sectional view illustrating an example of an eighteenth gate contact illustrated in FIG. 3.

FIG. 6 is a cross-sectional view illustrating an example of a fifteenth gate contact illustrated in FIG. 3.

FIG. 7 is a cross-sectional view illustrating an example of a twelfth gate contact illustrated in FIG. 3.

FIGS. 8, 9, 10, 11, 12, 13, 14, 15, 16, 17, 18, 19, and FIG. 20 are partial cross-sectional views illustrating an example of a manufacturing method of a semiconductor device.

FIGS. 21, 22, 23, and FIG. 24 are partial cross-sectional views illustrating an example of a manufacturing method of a semiconductor device.

FIG. 25 is a cross-sectional view illustrating an example of a portion of a semiconductor device.

FIG. 26 is a cross-sectional view illustrating an example of a portion of a semiconductor device.

FIG. 27 is a partial cross-sectional view schematically illustrating an example of a semiconductor device.

FIG. 28 is a partial cross-sectional view schematically illustrating an example of a semiconductor device.

FIG. 29 schematically illustrates an electronic system including an example of a semiconductor device.

FIG. 30 is a perspective view schematically illustrating an example of an electronic system including a semiconductor device.

FIG. 31 is a cross-sectional view schematically illustrating an example of a semiconductor package.

FIG. 32 is a cross-sectional view schematically illustrating an example of a semiconductor package.

### DETAILED DESCRIPTION

Implementations of the present disclosure will be described more fully hereinafter with reference to the accompanying drawings for those skilled in the art to which the present disclosure pertains to easily practice the present disclosure. The present disclosure may be implemented in various different forms and is not limited to the implementations provided herein.

A portion unrelated to the description is omitted in order to clearly describe the present disclosure, and same or similar components are denoted by a same reference numeral throughout the present specification.

Further, since a size and/or a thickness of a portion, a region, a member, a unit, a layer, a film, a substrate, or the like illustrated in the accompanying drawings may be arbitrarily illustrated for better understanding and convenience of explanation, the present disclosure is not limited to the illustrated size and/or thickness. In the drawings, a thickness of a portion, a region, a member, a unit, a layer, a film, a substrate, or the like may be enlarged or exaggerated for convenience of explanation and/or simple illustration.

It will be understood that when a component such as a portion, a region, a member, a unit, a layer, a film, a substrate, or the like is referred to as being “on” or “above” another component, it may be directly on another component or an intervening component may also be present. In contrast, when a component is referred to as being “directly on” another component, there is no intervening component. Further, when a component is referred to as being “on” or “above” a reference component, a component may be disposed on or below the reference component, and does not necessarily be “on” or “above” the reference component toward an opposite direction of gravity.

In addition, throughout the specification, unless explicitly described to the contrary, the word “comprise”, “include”, or “contain”, and variations such as “comprises”, “comprising”, “includes”, “including”, “contains”, or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a case where a cross-sectional view taken along a vertical direction is viewed from a side.

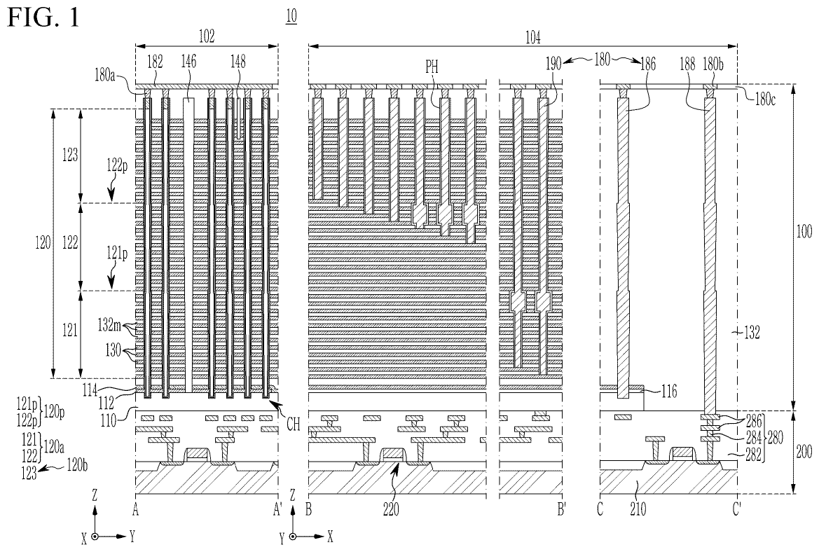

Hereinafter, referring to FIG. 1 to FIG. 20, a semiconductor device and a manufacturing method of the same will be described in detail.

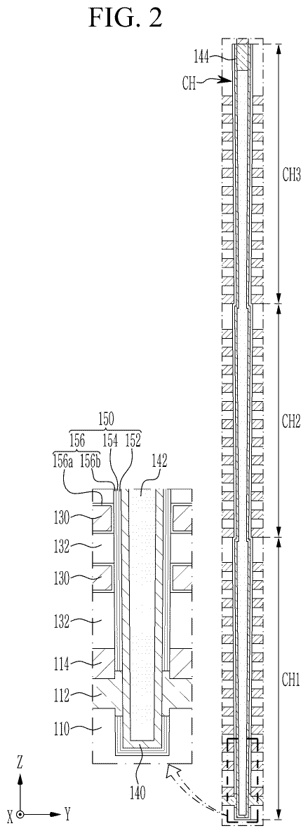

FIG. 1 is a partial cross-sectional view schematically illustrating an example of a semiconductor device 10. FIG. 2 is an enlarged cross-sectional view illustrating an example of a channel structure CH that is included in the semiconductor device 10 illustrated in FIG. 1. In FIG. 1, A-A′, B-B′ and C-C′ are illustrated for a clear understanding. In FIG. 1, positions of a source contact 186 and an input/output connection wiring 188 are conceptually illustrated.

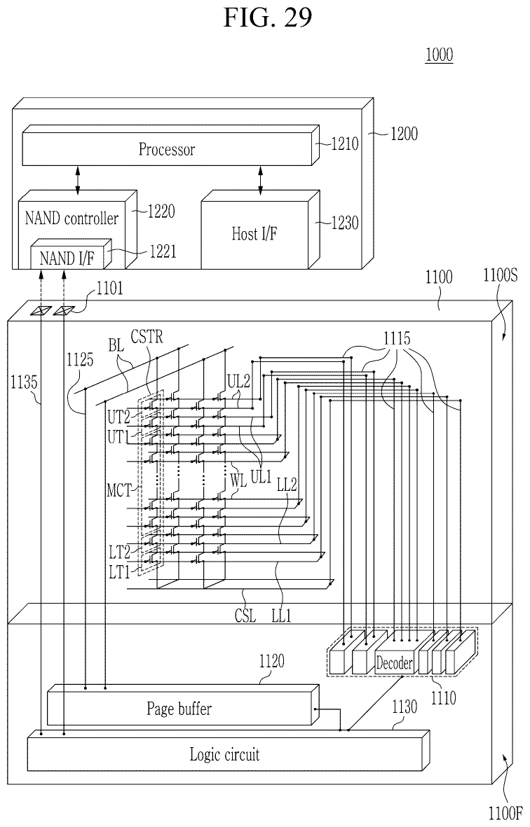

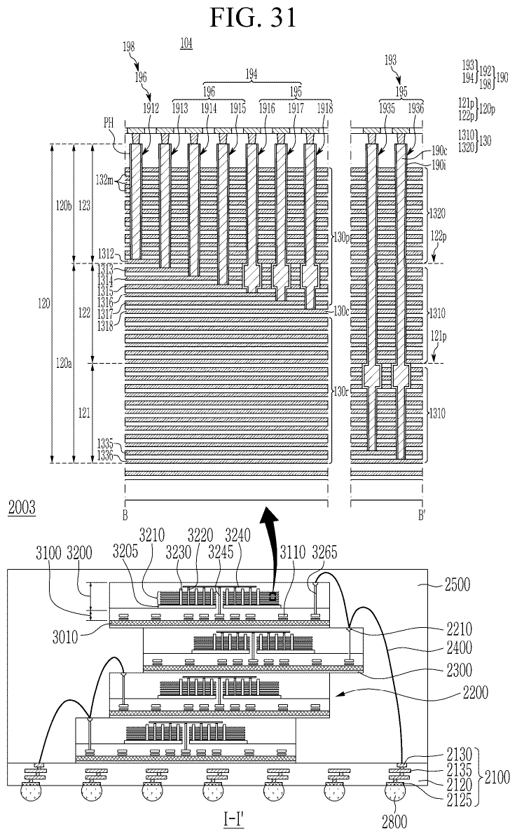

Referring to FIG. 1 and FIG. 2, a semiconductor device 10 may include a cell region 100 that includes a memory cell structure and a circuit region 200 that includes a peripheral circuit structure configured to control an operation of the memory cell structure. For example, the circuit region 200 and the cell region 100 may correspond to a first structure 1100F and a second structure 1100S of a semiconductor device 1100 included in an electronic system 1000 illustrated in FIG. 29, respectively. For example, the circuit region 200 and the cell region 100 may be portions including a first structure 3100 and a second structure 3200 of a semiconductor chip 2200 illustrated in FIG. 31, respectively.

The circuit region 200 may include the peripheral circuit structure on a first substrate 210, and the cell region 100 may include a gate stacking structure 120 and a channel structure CH on a second substrate 110 as the memory cell structure. The circuit region 200 may include a circuit wiring portion 280, and the cell region 100 may include a cell wiring portion 180 electrically connected to the memory cell structure.

In some implementations, the cell region 100 may be disposed on the circuit region 200. Accordingly, an area corresponding to the circuit region 200 does not need to be secured separately from the cell region 100. Therefore, an area of the semiconductor device 10 may be reduced. However, the implementations are not limited thereto, and the circuit region 200 may be disposed next to the cell region 100. Other various modified implementations are possible.

The circuit region 200 may include a first substrate 210, and a circuit element 220 and a circuit wiring portion 280 on a surface (an upper surface in FIG. 1) of the first substrate 210.

The first substrate 210 may be a semiconductor substrate including a semiconductor material. For example, the first substrate 210 may be a semiconductor substrate including or being formed of a semiconductor material or may be a semiconductor substrate in which a semiconductor layer is on a base substrate. For example, the first substrate 210 may include or be formed of single-crystalline or polycrystalline silicon, epitaxial silicon, germanium, silicon-germanium, silicon on insulator (SOI), germanium on insulator (GOI), or the like.

The circuit element 220 on the first substrate 210 may include any of various circuit elements that control an operation of the memory cell structure in the cell region 100. For example, the circuit element 220 may constitute the peripheral circuit structure such as a decoder circuit 1110 (refer to FIG. 29), a page buffer 1120 (refer to FIG. 29), a logic circuit 1130 (refer to FIG. 29), or the like.

The circuit element 220 may include, for example, a plurality of transistors, but the implementations are not limited thereto. For example, the circuit element 220 may include not only an active element such as the transistor or the like but also a passive element such as a capacitor, a resistor, an inductor, or the like.

The circuit wiring portion 280 on the first substrate 210 may be electrically connected to the circuit element 220. In some implementations, the circuit wiring portion 280 may include a plurality of wiring layers 286 that are spaced apart from each other while interposing an insulation layer 282 therebetween and are electrically connected by a contact via 284 to form a desired path. The wiring layer 286 or contact via 284 may include any of various conductive materials, and the insulation layer 282 may include any of various insulating materials. For example, the insulation layer 282 may include or be formed of at least one of silicon oxide, silicon nitride, and silicon oxynitride.

The cell region 100 may include a cell array region 102 and a connection region 104. In the cell array region 102, a gate stacking structure 120 and a channel structure CH may be disposed on the second substrate 110. A structure that connects the gate stacking structure 120 and/or the channel structure CH in the cell array region 102 to the circuit region 200 or an external circuit may be disposed in the cell array region 102 and/or the connection region 104.

In some implementations, the second substrate 110 may include a semiconductor layer including a semiconductor material. For example, the second substrate 110 may be a semiconductor substrate including or being formed of a semiconductor material or may be a semiconductor substrate in which a semiconductor layer is on a base substrate. For example, the second substrate 110 may include or be formed of silicon, germanium, silicon-germanium, silicon on insulator (SOI), germanium on insulator (GOI), or the like. A p-type dopant or an n-type dopant may be doped to the semiconductor layer included in the second substrate 110. For example, the p-type dopant may include boron (B), gallium (Ga), or the like, or the n-type dopant may include phosphorus (P), arsenic (As), or the like. However, the implementations are not limited to a material of the second substrate 110, a conductive type of the dopant doped to the semiconductor layer, or the like.

In the cell array region 102, the gate stacking structure 120 and the channel structure CH may be disposed. The gate stacking structure 120 may include interlayer insulation layers 132m and gate electrodes 130 alternately stacked on a surface (e.g., an upper surface) of the second substrate 110. The channel structure CH may extend in a thickness direction of the semiconductor device 10 (a Z-axis direction in the drawings) to pass through the gate stacking structure 120. The thickness direction of the semiconductor device 10 may be a direction (e.g., a vertical direction) that intersects (e.g., is perpendicular to) the second substrate 110.

In some implementations, horizontal conductive layers 112 and 114 may be provided between the second substrate 110 and the gate stacking structure 120 in the cell array region 102. The horizontal conductive layers 112 and 114 may electrically connect (e.g., directly connect) the channel structure CH and the second substrate 110. The horizontal conductive layers 112 and 114 may include a first horizontal conductive layer 112 and/or a second horizontal conductive layer 114 sequentially on the second substrate 110. The first horizontal conductive layer 112 may act as a portion of a common source line of the semiconductor device 10. For example, the first horizontal conductive layer 112 may act as the common source line together with the second substrate 110.

The first and second horizontal conductive layers 112 and 114 may include a semiconductor material (e.g., polycrystalline silicon). For example, the first horizontal conductive layer 112 may include a polycrystalline silicon layer including a dopant. However, the implementations are not limited thereto, and the second horizontal conductive layer 114 may include or be formed of a material (e.g., an insulating material) different from a material of the first horizontal conductive layer 112, or the second horizontal conductive layer 114 may be omitted.

The gate stacking structure 120 where cell insulation layers 132 (e.g., the interlayer insulation layers 132m) and the gate electrodes 130 are alternately stacked on each other may be disposed on the second substrate 110 (e.g., on the first and second horizontal conductive layers 112 and 114 disposed on the second substrate 110).

The gate electrode 130 may include any of various conductive materials. For example, the gate electrode 130 may include or be formed of a metallic material (e.g., tungsten (W), copper (Cu), aluminum (Al), or the like), polycrystalline silicon, metal nitride (e.g., titanium nitride (TiN), tantalum nitride (TaN), or the like), or a combination thereof. As illustrated in an enlarged portion of FIG. 2, a portion (e.g., a first blocking layer 156a) of a blocking layer 156 that includes or is formed of an insulating material may be disposed outside the gate electrode 130. The interlayer insulation layer 132m may include any of various insulating materials. For example, the interlayer insulation layer 132m may include or be formed of at least one of silicon oxide, silicon nitride, silicon oxynitride, and a low dielectric constant material having a lower dielectric constant than silicon oxide, or may include or be formed of a combination thereof.

In some implementations, the channel structure CH may include a channel layer 140, and a gate dielectric layer 150 on the channel layer 140 between the gate electrode 130 and the channel layer 140. The channel structure CH may further include a core insulation layer 142 at an inside of the channel layer 140. In some implementations, the core insulation layer 142 may be omitted. The channel structure CH may further include a channel pad 144 on the core insulation layer 142, the channel layer 140, and/or the gate dielectric layer 150. The gate dielectric layer 150 between the gate electrode 130 and the channel layer 140 may include a tunneling layer 152, a charge storage layer 154, and a blocking layer 156 sequentially on the channel layer 140.

Each channel structure CH may form one memory cell string, and a plurality of channel structures CH may be spaced apart from each other while forming rows and columns in a plan view. For example, a plurality of channel structures CH may be disposed to form any of various shapes such as a lattice shape, a zigzag shape, or the like in a plan view. The channel structure CH may have a pillar shape. For example, in a cross-sectional view, the channel structure CH may have an inclined side surface such that a width of the channel structure CH decreases toward the second substrate 110 due to a high aspect ratio. However, the implementations are not limited thereto, and an arrangement, a structure, a shape, or the like of the channel structure CH may be variously modified.

The channel layer 140 may include a semiconductor material (e.g., polycrystalline silicon). The core insulation layer 142 may include any of various insulating materials. For example, the core insulation layer 142 may include or be formed of silicon oxide, silicon nitride, silicon oxynitride, or a combination thereof.

The tunneling layer 152 may include an insulating material that is capable of tunneling a charge (e.g., silicon oxide, silicon oxynitride, or the like). The charge storage layer 154 may be used as a data storage region, and the charge storage layer 154 may include polycrystalline silicon, silicon nitride, or the like. The blocking layer 156 may include an insulating material that is capable of preventing an undesirable flow of charge into the gate electrode 130. For example, the blocking layer 156 may include or be formed of silicon oxide, silicon nitride, silicon oxynitride, a high dielectric constant material having a higher dielectric constant than silicon oxide, or a combination thereof. In some implementations, the blocking layer 156 may include a first blocking layer 156a that includes a portion horizontally extending on the gate electrode 130, and a second blocking layer 156b that vertically extends between the first blocking layer 156a and the charge storage layer 154.

However, materials, stacking structures, or the like of the channel layer 140, the core insulation layer 142, and the gate dielectric layer 150 may be variously modified, and the implementations are not limited thereto.

The channel pad 144 may cover an upper surface of the core insulation layer 142 and be disposed to be electrically connected to the channel layer 140. The channel pad 144 may include a conductive material (e.g., polycrystalline silicon doped with a dopant), but the implementations are not limited thereto.

In some implementations, the gate stacking structure 120 may include a plurality of stacking portions that are sequentially stacked. Thereby, a number of stacked gate electrodes 130 may increase and thus a number of memory cells may increase with a stable structure.

In some implementations, the plurality of stacking portions may include a first stacking portion 120a and a second stacking portion 120b. The first stacking portion 120a may include at least one gate stacking portion, and the second stacking portion 120b may be disposed on the first stacking portion 120a. The first stacking portion 120a may be a lower or intermediate stacking portion of the plurality of stacking portions, and the second stacking portion 120b may be an upper stacking portion of the plurality of stacking portions.

In FIG. 1, it is illustrated as an example that the gate stacking structure 120 or the plurality of stacking portions include first to third gate stacking portions 121, 122, and 123. That is, the first gate stacking portion 121 and the second gate stacking portion 122 may be the first stacking portion 120a, and the third gate stacking portion 123 may be the second stacking portion 120b.

The first stacking portion 120a may include a plurality of gate electrodes 130 (e.g., a plurality of first electrodes) and a plurality of interlayer insulation layers 132m alternately stacked on each other. For example, the first gate stacking portion 121 may include a plurality of gate electrodes 130 (e.g., a plurality of first electrodes) and a plurality of interlayer insulation layers 132m alternately stacked on each other, and the second gate stacking portion 122 may include a plurality of gate electrodes 130 (e.g., a plurality of first electrodes) and a plurality of interlayer insulation layers 132m alternately stacked on each other. The second stacking portion 120b may include a plurality of gate electrodes 130 (e.g., a plurality of second electrodes) and a plurality of interlayer insulation layers 132m alternately stacked on each other.

However, the implementations are not limited thereto, and the gate stacking structure 120 or the plurality of stacking portions may include two, or four or more gate stacking portions.

When the plurality of stacking portions or a plurality of gate stacking portions (e.g., the first to third gate stacking portions 121, 122, and 123) are provided as in the above, the channel structure CH may include a plurality of channel portions (e.g., first to third channel portions CH1, CH2, and CH3). Each of the plurality of channel portions (e.g., the first to third channel portions CH1, CH2, and CH3) may pass through the plurality of gate stacking portions (e.g., the first to third gate stacking portions 121, 122, and 123), respectively. The plurality of channel portions may be connected to each other. In a cross-sectional view, each of the plurality of channel portions (e.g., the first to third channel portions CH1, CH2, and CH3) may have an inclined side surface such that a width of each of the plurality of channel portions decreases toward the second substrate 110 due to a high aspect ratio. A bent portion due to a difference in widths of the plurality of channel portions (e.g., the first to third channel portions CH1, CH2, and CH3) may be provided at a boundary of the plurality of channel portions (e.g., the first to third channel portions CH1, CH2, and CH3). In some implementations, the plurality of channel portions may have an inclined side surface that continuously extends without the bent portion. In FIG. 2, it is illustrated as an example that each of the gate dielectric layer 150, the channel layer 140, and the core insulation layer 142 of the plurality of channel portions continuously extends to have an integral structure. In some implementations, gate dielectric layers 150, channel layers 140, and core insulation layers 142 of the plurality of channel portions may be separately formed and be electrically connected to each other. In some implementations, a separate channel pad may be additionally disposed at the boundary of the plurality of channel portions. As such, the implementations are not limited to a shape of the plurality of channel portions.

In some implementations, the gate stacking structure 120 may be divided into a plurality of portions in a plan view by a separation structure 146. The separation structure 146 may extend in the thickness direction of the semiconductor device 10 (the Z-axis direction in the drawings) to pass through or penetrate the gate stacking structure 120. An upper separation region 148 may be disposed in an upper portion of the gate stacking structure 120. In a plan view, the separation structure 146 and/or the upper separation region 148 may extend in an extension direction of the gate electrode 130 (an X-axis direction in the drawings). A plurality of separation structures 146 and/or a plurality of upper separation regions 148 may be spaced apart from each other at predetermined intervals in an intersection direction (a Y-axis direction in the drawings) that intersects the gate electrode 130.

The separation structure 146 or the upper separation region 148 may include any of various insulating materials. For example, the separation structure 146 or the upper separation region 148 may include or be formed of an insulating material, such as, silicon oxide, silicon nitride, or silicon oxynitride. However, the implementations are not limited thereto, and a structure, a shape, a material, or the like of the separation structure 146 or the upper separation region 148 may be variously modified.

The connection region 104 and the cell wiring portion 180 may be provided to connect the gate stacking structure 120 and the channel structure CH in the cell array region 102 to the circuit region 200 or the external circuit. The connection region 104 may be disposed at a periphery of the cell array region 102, and a part of penetration contacts 170 and a portion of the cell wiring portion 180 may be disposed in the connection region 104.

The cell wiring portion 180 may include any of members configured to electrically connect the gate electrode 130, the channel structure CH, the horizontal conductive layers 112 and 114, and/or the second substrate 110 to the circuit region 200 or external circuit. For example, the cell wiring portion 180 may include a bit line 182, a gate contact 190, a source contact 186, an input/output connection wiring 188, and a contact via 180a and a connection wiring 180b connected thereto.

The bit line 182 may extend in the intersection direction (the Y-axis direction in the drawings) that intersects (e.g., is perpendicular to) the extension direction of the gate electrode 130 (the X-axis direction in the drawings). The bit line 182 may be electrically connected to the channel structure CH (e.g., the channel pad 144) through the contact via 180a (e.g., a bit line contact via) that passes through a cell insulation layer 132.

In some implementations, the gate stacking structure 120 may be disposed in the cell array region 102 and the connection region 104. For example, in the connection region 104, extension lengths of the plurality of gate electrodes 130 may be substantially same. Substantially same may refer to have a difference within a process error (e.g., less than 10%). In the connection region 104, each of the plurality of gate contacts 190 may pass through a portion of the gate stacking structure 120 and be electrically connected to one of the plurality of gate electrodes 130.

In some implementations, a portion (e.g., a pad region) in which the gate stacking structure 120 is removed to have a stair shape for an electrical connection between the gate electrode 130 and the gate contact 190 or an insulation layer (e.g., a pad insulation layer) in the portion may not be provided. A connection structure between the plurality of gate contacts 190 and the plurality of gate electrodes 130 will be described later in more detail.

In the connection region 104, the source contact 186 may pass through the cell insulation layer 132 and be electrically connected to the horizontal conductive layers 112 and 114 and/or the second substrate 110. In the connection region 104, the input/output connection wiring 188 may pass through the gate stacking structure 120 or be disposed outside the gate stacking structure 120 to be electrically connected to the circuit wiring portion 280 of the circuit region 200. The cell insulation layer 132 may include the interlayer insulation layer 132m, and an insulation layer on the gate stacking structure 120 and/or at a periphery of the gate stacking structure 120.

In FIG. 1, it is illustrated as an example that the source contact 186 and/or the input/output connection wiring 188 has an inclined side surface such that a width of the source contact 186 and/or the input/output connection wiring 188 decreases toward the second substrate 110 due to an aspect ratio, and a bent portion is provided at a boundary 120p of the plurality of gate stacking portions (e.g., a first boundary 121p at an upper portion of the first gate stacking portion 121 or a second boundary 122p at an upper portion of the second gate stacking portion 122) in a cross-sectional view. However, the implementations are not limited thereto. In some implementations, the source contact 186 and/or the input/output connection wiring 188 may not include the bent portion at the boundary 120p of the plurality of gate stacking portions. Other various modified implementations are possible.

For a clear understanding and simple illustration, it is illustrated as an example that the connection wiring 180b includes a single wiring layer disposed on a plane same as the bit line 182, and an insulation layer 180c is disposed in a region other the connection wiring 180b. However, the implementations are not limited thereto. In some implementations, the connection wiring 180b may include a plurality of wiring layers and may further include a contact via for an electrical connection with the bit line 182, the gate contact 190, the source contact 186, and/or the input/output connection wiring 188.

The cell wiring portion 180 may be electrically connected to the circuit wiring portion 280, and therefore, the channel structure CH, the gate electrode 130, the horizontal conductive layers 112 and 114, and/or the second substrate 110 may be electrically connected to the circuit element 220 of the circuit region 200.

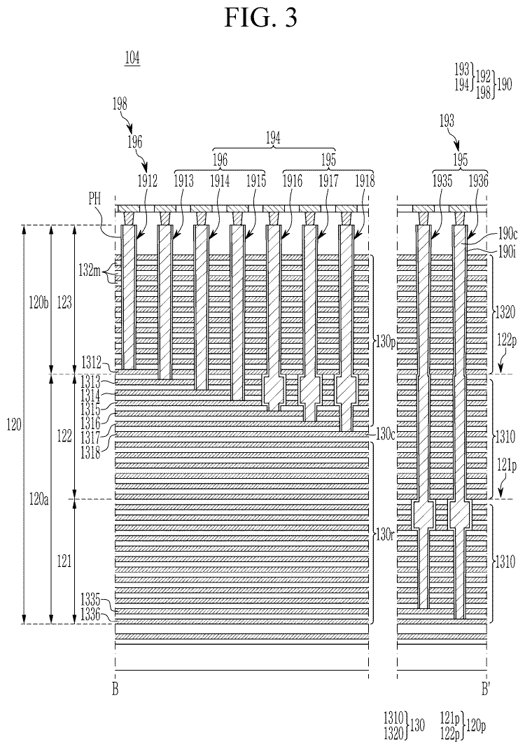

Referring to FIG. 3 to FIG. 7 together with FIG. 1, a connection structure between the plurality of gate contacts 190 and the plurality of gate electrodes 130 will be described in detail.

FIG. 3 is a cross-sectional view illustrating an example of the connection region 104 of the cell region 100 that is included in the semiconductor device 10 illustrated in FIG. 1. FIG. 3 illustrates the connection region 104 of the cell region 100 in a B-B′ portion in FIG. 1. In FIG. 3, it is illustrated as an example that the gate electrode 130 includes first to thirty-sixth gate electrodes. FIG. 3 mainly illustrates twelfth to eighteenth gate contacts 1912 to 1918 electrically connected to twelfth to eighteenth gate electrodes 1312 to 1318, respectively, and thirty-fifth and thirty-sixth gate contacts 1935 and 1936 electrically connected to thirty-fifth and thirty-sixth gate electrodes 1335 and 1336, respectively.

Referring to FIG. 1 and FIG. 3, in some implementations, in the connection region 104, each of a plurality of gate contacts 190 may pass through a portion of the gate stacking structure 120 and be electrically connected to (e.g., in contact with) one of the plurality of gate electrodes 130.

For example, each gate contact 190 may extend downward from an upper surface of the gate stacking structure 120 to a lower surface of the gate stacking structure 120. Each gate contact 190 may pass through a portion of the gate stacking structure 120 in the thickness direction of the semiconductor device 10 (the Z-axis direction in the drawings). The thickness direction of the semiconductor device 10 may intersect the second substrate 110. For example, the thickness direction of the semiconductor device 10 may be a vertical direction that is perpendicular to the second substrate 110. The upper surface of the gate stacking structure 120 may be a surface adjacent to the cell wiring portion 180 or opposite to the second substrate 110 in the thickness direction of the semiconductor device 10. The lower surface of the gate stacking structure 120 may be a surface opposite to the cell wiring portion 180 or adjacent to the second substrate 110 in the thickness direction of the semiconductor device 10. Unless otherwise described, with respect to the cell region 100, an upper portion or an upper surface may refer to a portion or a surface adjacent to the cell wiring portion 180 or opposite to the second substrate 110, and a lower portion or a lower surface may refer to a portion or a surface opposite to the cell wiring portion 180 or adjacent to the second substrate 110.

The plurality of gate contacts 190 may be connected to the plurality of gate electrodes 130, respectively. In the thickness direction of the semiconductor device 10 (the Z-axis direction in the drawings), the plurality of gate electrodes 130 may be disposed at different heights or different levels, and the plurality of gate contacts 190 may have different lengths or different depths to reach the plurality of gate electrodes 130, respectively.

Each gate contact 190 may pass through a portion of the gate stacking structure 120 to have a depth capable of reaching a connection gate electrode 130c of the plurality of gate electrodes 130. For example, a first gate contact may be electrically connected to a first gate electrode. An n-th gate contact may be electrically connected an n-th gate electrode, and a k-th gate contact may be electrically connected a k-th gate electrode. The n may be a natural number greater than 1 and less than k, and the k may be a total number of the plurality of gate electrodes 130 or a total number of the plurality of gate contacts 190.

In the drawings, it is illustrated as an example that the gate electrode 130 includes first to thirty-sixth gate electrodes. First to eleventh gate contacts may be electrically connected to first to eleventh gate electrodes, respectively. Twelfth to eighteenth gate contacts 1912 to 1918 may be electrically connected to twelfth to eighteenth gate electrodes 1312 to 1318, respectively. Nineteenth to thirty-fourth gate contacts may be electrically connected to nineteenth to thirty-fourth gate electrodes, respectively. Thirty-fifth and thirty-sixth gate contacts 1935 and 1936 may be electrically connected to thirty-fifth and thirty-sixth gate electrodes 1335 and 1336, respectively. As in the above, the plurality of gate contacts 190 may be electrically connected to the plurality of gate electrodes 130, respectively.

For a clear understanding and simple illustration, in the drawings, it is illustrated as an example that the depths of the plurality of gate contacts 190 may sequentially increase away from the cell array region 102, but the implementations are not limited thereto. An arrangement of the plurality of gate contacts 190 may be variously modified.

Based on one gate contact 190, a plurality of gate electrodes 130 may include a connection gate electrode 130c electrically connected to one gate contact 190, and may include a penetrated gate electrode 130p and/or a remaining gate electrode 130r. The penetrated gate electrode 130p may be passed through by the gate contact 190, and be electrically insulated from the gate contact 190 by a side insulation layer 190i of the gate contact 190. The penetrated gate electrode 130p may refer to a gate electrode 130 above the connection gate electrode 130c. The remaining gate electrode 130r may not be passed through by the gate contact 190, and be electrically insulated from the gate contact 190. The remaining gate electrode 130r refer to a gate electrode 130 below the connection gate electrode 130c.

In the first gate contact, the first gate electrode may be the connection gate electrode 130c, and a gate electrode 130 below the connection gate electrode 130c may be the remaining gate electrode 130r. In the n-th gate contact, the n-th gate electrode may be the connection gate electrode 130c, a gate electrode 130 above the connection gate electrode 130c may be the penetrated gate electrode 130p, and a gate electrode 130 below the connection gate electrode 130c may be the remaining gate electrode 130r. In the k-th gate contact (e.g., the thirty-sixth gate contact 1936 in FIG. 3), the k-th gate electrode (e.g., the thirty-sixth gate electrode 1336 in FIG. 3) may be the connection gate electrode 130c, a gate electrode 130 above the connection gate electrode 130c may be the penetrated gate electrode 130p, and a gate electrode 130 below the connection gate electrode 130c may be the remaining gate electrode 130r. For a clear understanding, FIG. 3 illustrates the connection gate electrode 130c, the penetrated gate electrode 130p, and the remaining gate electrode 130r based on the eighteenth gate contact 1918.

In some implementations, each gate contact 190 may be electrically connected to (e.g., be in contact with) an upper surface of the connection gate electrode 130c. However, the implementations are not limited thereto. Each gate contact 190 may be electrically connected to (e.g., in contact with) another portion (e.g., a side surface) of the connection gate electrode 130c.

In some implementations, each gate contact 190 may include a conductive portion 190c, and a side insulation layer 190i between the conductive portion 190c and the gate stacking structure 120.

In each gate contact 190, the side insulation layer 190i may be disposed at least between a side surface of the conductive portion 190c and a side surface of the penetrated gate electrode 130p, and may electrically insulate the conductive portion 190c and the penetrated gate electrode 130p. The side insulation layer 190i may not be disposed on a lower surface of the conductive portion 190c and/or an upper surface of the connection gate electrode 130c. That is, the side insulation layer 190i may not be disposed between the upper surface of the connection gate electrode 130c and the lower surface of the gate contact 190. For example, a lower surface of the side insulation layer 190i may be in contact with the connection gate electrode 130c, or may be disposed between an upper surface and a lower surface of the interlayer insulation layer 132m that is disposed on or above the connection gate electrode 130c.

Thereby, the side insulation layer 190i may surround the entirety of the side surface of the gate contact 190 corresponding to the penetrated gate electrode 130p, and may stably electrically insulate the gate contact 190 and the penetrated gate electrode 130p. However, the implementations are not limited thereto, and a position of the side insulation layer 190i, a connection position of the gate contact 190 and the connection gate electrode 130c may be variously modified.

For example, the conductive portion 190c may have a pillar shape (e.g., a pillar shape having a planar shape of a circular shape, a polygonal shape, an oval shape, or the like), and the side insulation layer 190i may have any of various planar shapes such as an annular shape, a ring shape, a frame shape, or the like to surround the conductive portion 190c.

In some implementations, each gate contact 190 may be disposed in each through hole PH and be electrically connected to an upper portion of the connection gate electrode 130c. For example, a plurality of through holes PH may individually pass through the gate stacking structure 120 and be spaced apart from each other while interposing the gate stacking structure 120 therebetween, one gate contact 190 may be disposed in one through hole PH, and a lower surface of the conductive portion 190c of one gate contact 190 in one through hole PH may be disposed on (e.g., in contact with) an upper surface of the gate electrode 130c. In some implementations, the plurality of gate contacts 190 may be in the plurality of through holes PH, respectively, that are spaced apart from each other such that the plurality of gate contacts 190 one-to-one correspond the plurality to through holes PH. In some implementations, the through hole PH may have any of various planar shapes (e.g., a circular shape, a polygonal shape, an oval shape, or the like), and the implementations are not limited to a planar shape of the through hole PH.

Accordingly, a pad region (e.g., a pad insulation layer) through which a plurality of gate contacts 190 pass together, or an additional insulation layer (e.g., a pad insulation layer) that is other than the interlayer insulation layer 132m and is disposed between the plurality of gate contacts 190, and a portion (e.g., the pad region) in which the gate stacking structure 120 is removed to have a stair shape for an electrical connection between the gate electrode 130 and the gate contact 190 may not be provided. That is, the plurality of gate contacts 190 may be individually electrically connected to the plurality of gate electrodes 130, respectively, without the pad region or the pad insulation layer. Accordingly, a process of electrically connecting the gate contact 190 and the gate electrode 130 may be simplified, and an area of the connection region 104 may be reduced.

On the other hand, in a comparative example including a pad region, a process of etching a portion of a gate stacking structure (e.g., a process of forming a portion of a stair shape), a process of forming a pad insulation layer covering the stair shape of the gate stacking structure, and a process of electrically connecting a plurality of gate contacts that pass through one pad insulation layer to a plurality of gate electrodes, respectively, may be performed. Accordingly, the process of forming the pad region and the process of forming the gate contact may be complicated. In the pad region or the pad insulation layer through which the plurality of gate contacts pass, an interval between the plurality of gate contacts may be increased to prevent a mis-alignment of the gate contact. Accordingly, an area of a connection region may be large.

In some implementations, the plurality of gate contacts 190 may include a first contact 192 and a second contact 198. The first contact 192 may be electrically connected to a first electrode 1310 included in a first stacking portion 120a, and the second contact 198 may be electrically connected to a second electrode 1320 included in a second stacking portion 120b. The first contact 192 may include a first shaped contact 195 having a first shape, and may further include a second shaped contact 196 having a shape (e.g., a second shape) different from the first shape. The second contact 198 may have a second shape different from the first shape. For example, the second contact 198 may be the second shaped contact 196 having the second shape.

The at least one gate stacking portion included in the first stacking portion 120a may include a plurality of gate stacking portions, and the first contact 192 may include a plurality of connection contacts electrically connected to the plurality of gate stacking portions. For example, the first contact 192 may include a plurality of first connection contacts 193 and a plurality of second connection contacts 194. The plurality of first connection contacts 193 may be electrically connected to a plurality of first electrodes 1310 included in a first gate stacking portion 121. The plurality of second connection contacts 194 may be electrically connected to a plurality of first electrodes 1310 included in a second gate stacking portion 122. The first contact 192 (e.g., a plurality of second connection contacts 194) connected to a first electrode 1310 included in the first stacking portion 120a (e.g., the second gate stacking portion 122) adjacent to the second stacking portion 120b may include the second shaped contact 196.

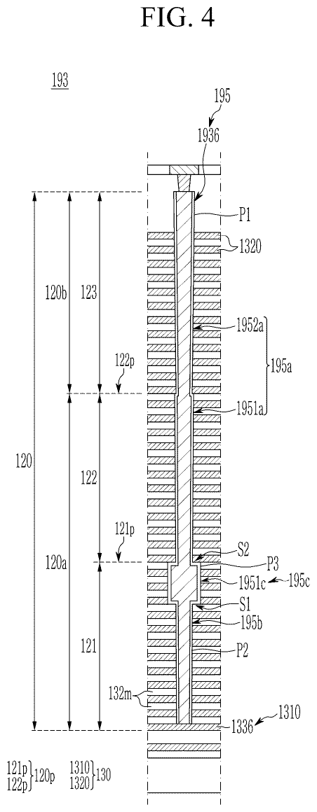

Referring to FIG. 4 to FIG. 7 together with FIG. 3, the first shaped contact 195 and the second shaped contact 196 will be described in detail.

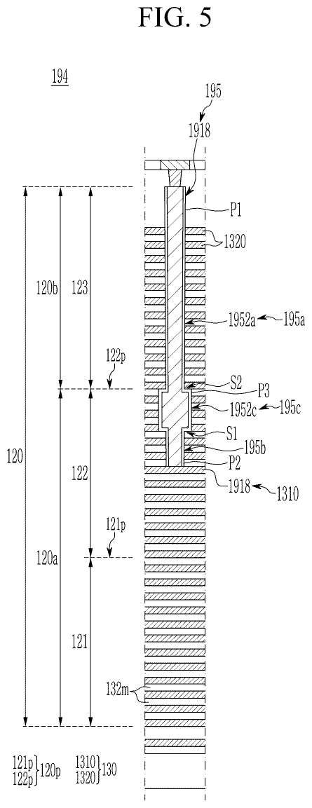

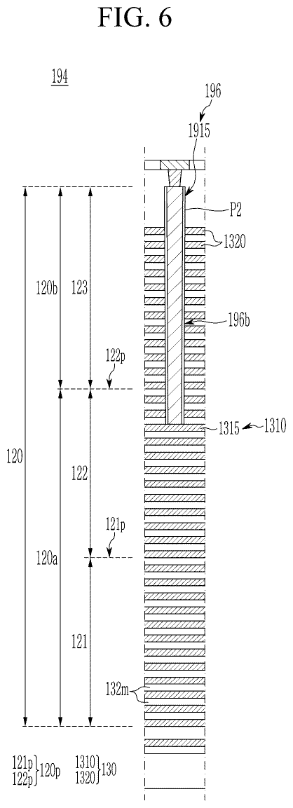

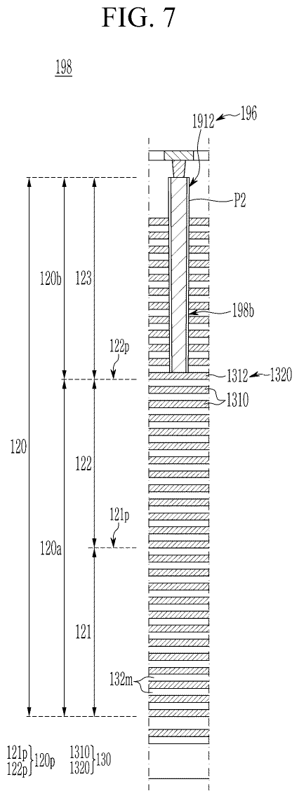

FIG. 4 is a cross-sectional view illustrating an example of the thirty-sixth gate contact 1936 illustrated in FIG. 3. FIG. 5 is a cross-sectional view illustrating an example of the eighteenth gate contact 1918 illustrated in FIG. 3. The thirty-sixth gate contact 1936 illustrated in FIG. 4 and the eighteenth gate contact 1918 illustrated in FIG. 5 may be examples of the first shaped contact 195. FIG. 6 is a cross-sectional view illustrating an example of the fifteenth gate contact 1915 illustrated in FIG. 3. FIG. 7 is a cross-sectional view illustrating an example of the twelfth gate contact 1912 illustrated in FIG. 3. The fifteenth gate contact 1915 illustrated in FIG. 6 and the twelfth gate contact 1912 illustrated in FIG. 7 may be examples of the second shaped contact 196.

Referring to FIG. 3 to FIG. 5, in some implementations, the first connection contact 193 may be the first shaped contact 195, and at least a part of second connection contacts 194 (e.g., one or more second connection contacts 194) may be the first shaped contact 195.

The first shaped contact 195 having the first shape may include an extension part 195a, a connection part 195b (e.g., a first connection part), and an expanded part 195c. The extension part 195a may pass through at least the second stacking portion 120b (e.g., the third gate stacking portion 123), and the connection part 195b may pass through a portion of the first stacking portion 120a and may be electrically connected to the first electrode 1310. The expanded part 195c may be disposed between the extension part 195a and the connection part 195b, and may be adjacent to one of the boundaries 120p of the plurality of gate stacking portions. The expanded part 195c may protrude from the connection part 195b in a horizontal direction, and/or may protrude from the extension part 195a in a horizontal direction.

The extension part 195a may include an extension portion (e.g., a first or second extension portion 1951a or 1952a) extending to pass through one gate stacking portion (e.g., the second or third gate stacking portion 122 or 123). For example, each extension portion (e.g., the first or second extension portion 1951a or 1952a) may pass through the entirety of one gate stacking portion (e.g., the second or third gate stacking portion 122 or 123). Each extension portion (e.g., the first or second extension portion 1951a or 1952a) may have an inclined side surface such that a width of the each extension portion decreases from an upper portion (e.g., an end of the extension part 195a opposite to the expanded part 195c) to a lower portion (e.g., the other end of the extension part 195a adjacent to the expanded part 195c) or the boundary 120p. That is, the extension part 195a may include the extension portion (e.g., the first or second extension portion 1951a or 1952a) having the inclined side surface such that the width of the extension portion (e.g., the first or second extension portion 1951a or 1952a) decreases toward the expanded part 195c.

Each extension portion (e.g., the first or second extension portion 1951a or 1952a) may be disposed in a first through portion P1 formed by a first etching process. For example, the first etching process may include a high aspect ratio contact (HARC) etching process. For example, in the first etching process, a portion of a channel through portion in which a portion of the channel structure CH is disposed and a portion of the first through portion P1 may be formed by using the high aspect ratio contact etching process.

The connection part 195b may extend to pass through a portion of one gate stacking portion (e.g., the first or the second gate stacking portion 121 or 122) and be electrically connected to the first electrode 1310. For example, the connection part 195b may have an inclined side surface such that a width of the connection part 195b decreases from an upper portion (e.g., an end of the connection part 195b adjacent to the expanded part 195c) to a lower portion (e.g., the other end of the connection part 195b opposite to the expanded part 195c). That is, the connection part 195b may have the inclined side surface such that the width of the connection part 195b decreases far away from the expanded part 195c.

The connection part 195b may be disposed in a second through portion P2 formed by a second etching process different from the first etching process. For example, the second etching process may include a plurality of partial etching processes using a binary system.

In some implementations, the second through portion P2 or the connection part 195b may have a relatively small length. The length of the second through portion P2 or the connection part 195b may refer to a length in the thickness direction of the semiconductor device 10 (the Z-axis direction in the drawings) or in the vertical direction. For example, the length of the second through portion P2 or the connection part 195b may be less than a thickness of one gate stacking portion (e.g., one of the first to third gate stacking portions 121, 122, and 123), a length of the first extension portion 1951a, or a length of the second extension portion 1952a.

That is, by including the first through portion P1 formed by the first etching process, the length of the second through portion P2 according to the binary system may decrease.

The expanded part 195c may be disposed between the connection part 195b and the extension part 195a and connect the connection part 195b and the extension part 195a. The expanded part 195c may have a side surface (e.g., a discontinuous side surface) that is not disposed on a same plane as a side surface of the connection part 195b and/or the extension part 195a, or may be a portion having a width greater than a width of the connection part 195b and/or the extension part 195a.

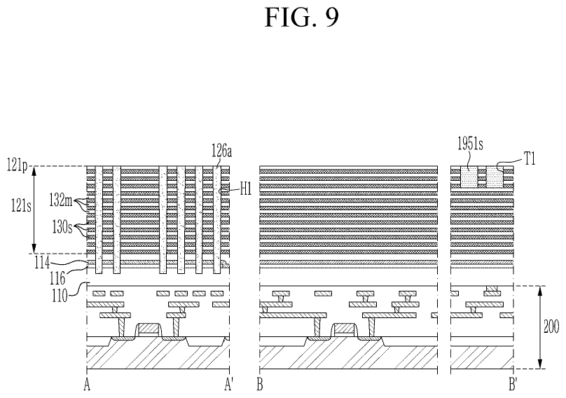

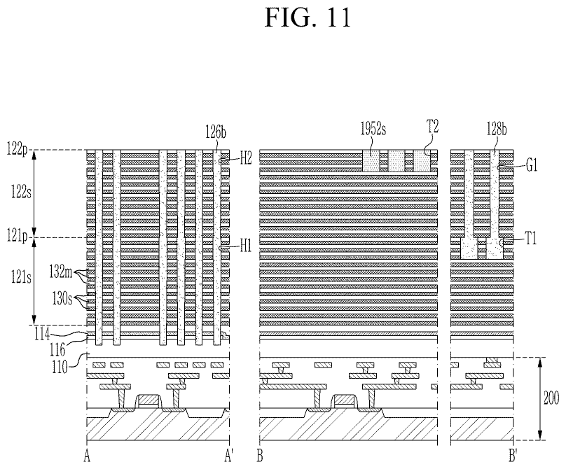

The expanded part 195c may be disposed in an expanded through portion P3 The expanded through portion P3 may be a portion where an etch stopping pattern was disposed. The etch stopping pattern may be provided such that the etching for forming the first through portion P1 may be stopped at a desired position in the first etching process of forming the first through portion P1. For example, the expanded through portion P3 may correspond to a trench (e.g., a first trench T1 (refer to FIG. 9) where an etch stopping pattern (e.g., a first etch stopping pattern 1951s (refer to FIG. 9) is disposed or a second trench T2 (refer to FIG. 11) where an etch stopping pattern (e.g., a second etch stopping pattern 1952s (refer to FIG. 11) is disposed).

In the first etching process of forming the first through portion P1 using the high aspect ratio contact etching process, it may be difficult for the first through portion P1 (e.g., at least a portion of the first through portion P1) to accurately stop at the boundary 120p of the gate stacking portion. In some implementations, by the etch stopping pattern at the boundary 120p of the gate stacking portion, the etching may be stably stopped at a desired position.

For example, in some implementations, a width (e.g., a maximum width or a maximum diameter) of the gate contact 190 may be greater than a width (e.g., a maximum width or a maximum diameter) of a channel structure CH (refer to FIG. 1). For example, a width of the extension part 195a, a width of the connection part 195b, a width (e.g., a maximum width or a maximum diameter) of the expanded part 195c may be greater than the width (e.g., the maximum width or the maximum diameter) of the channel structure CH. When the width of the gate contact 190 is relatively large, it may be more difficult for the first through portion P1 to accurately stop at the boundary 120p of the gate stacking portion. In some implementations, by the etch stopping pattern, the etching may be stably stopped at a desired position. The etch stopping pattern will be described later in detail in a manufacturing method of a semiconductor device 10.

The expanded part 195c may protrude from the connection part 195b in a horizontal direction, and/or may protrude from the extension part 195a in the horizontal direction. The etch stopping pattern in the expanded through portion P3 may have a width or an area greater than a width or an area of the second through portion P2 and/or the first through portion P1 considering a process error (a position difference in a plan view).

A width of the expanded part 195c adjacent to the connection part 195b may be greater than a width of the connection part 195b adjacent to the expanded part 195c, and/or a width of the expanded part 195c adjacent to the extension part 195a may be greater than a width of the extension part 195a adjacent to the expanded part 195c. For example, the width of the expanded part 195c adjacent to the connection part 195b, the width of the connection part 195b adjacent to the expanded part 195c, the width of the expanded part 195c adjacent to the extension part 195a, or the width of the extension part 195a adjacent to the expanded part 195c may refer to a maximum width (e.g., a maximum diameter). Thereby, the etch stopping pattern may have a sufficient width or area, and the etching may be stopped at a desired position even if there is a process error.

For example, a ratio of the width of the expanded part 195c to the width of the connection part 195b in a portion where the expanded part 195c and the connection part 195b are adjacent to each other or a ratio of the width of the expanded part 195c to the width of the extension part 195a in a portion where the expanded part 195c and the extension part 195a are adjacent to each other may be in a range of 1.1 or more. For example, the ratio of the width of the expanded part 195c to the width of the connection part 195b in the portion where the expanded part 195c and the connection part 195b are adjacent to each other or the ratio of the width of the expanded part 195c to the width of the extension part 195a in the portion where the expanded part 195c and the extension part 195a are adjacent to each other may be in a range of 3 or less (e.g., 2 or less). Thereby, even if there is a process error (the position difference in a plan view), the etching may be stably stopped and the area of the extension part 195c may be prevented from being too large. However, the implementations are not limited thereto. For example, the ratio of the width of the expanded part 195c to the width of the connection part 195b in the portion where the expanded part 195c and the connection part 195b are adjacent to each other or the ratio of the width of the expanded part 195c to the width of the extension part 195a in the portion where the expanded part 195c and the extension part 195a are adjacent to each other may be less than 1.1 or be greater than 3.

For example, a width (e.g., a maximum width) of the expanded part 195c at the boundary 120p may be greater than a width (e.g., a maximum width) of the gate contact 190 at an upper portion of the gate stacking structure 120. Thereby, even if there is a process error (the position difference in a plan view), the etching may be stably stopped by the etching stopping pattern. In a comparative example in which an etch stopping pattern is not included, if a gate contact have a step or a bent portion at a boundary of a gate stacking portion, a width of the gate contact (e.g., a maximum width) at the boundary may be same as or less than a width (e.g., a maximum width) of the gate contact at an upper portion of the gate stacking structure.

A first step S1 may be disposed between the expanded part 195c and the connection part 195b by a difference in width of the expanded part 195c and the connection part 195b, and a second step S2 may be disposed between the extension part 195a and the expanded part 195c by a difference in width of the extension part 195a and the expanded part 195c. In FIG. 4 and FIG. 5, it is illustrated as an example that the first shaped contact 195 has the first step S1 and the second step S2, but the implementations are not limited thereto. In some implementations, the first step S1 may be included without the second step S2, or the second step S2 may be included without the first step S1.

The extension part 195a, the connection part 195b, or the expanded part 195c may have a planar shape of a circular shape, a polygonal shape, an oval shape, or the like. However, the implementations are not limited thereto, and the extension part 195a, the connection part 195b, or the expanded part 195c may have any of various planar shapes.

In some implementations, the expanded part 195c may be adjacent to the boundary 120p (e.g., the boundary 120p at the upper portion of each gate stacking portion) between two adjacent gate stacking portions. A gate stacking portion may be formed and an etch stopping pattern may be formed at an upper portion of the gate stacking portion, and thereafter, another gate stacking portion may be formed. Therefore, the etch stopping pattern may be adjacent to the boundary 120p between two gate stacking portions (e.g., the boundary 120p at the upper portion of each gate stacking portion). Accordingly, the expanded part 195c in the expanded through portion P3 in which the etch stopping pattern was disposed may be adjacent to the boundary 120p between two adjacent gate stacking portions (e.g., the boundary 120p at the upper portion of each gate stacking portion).

For example, the expanded part 195c may be adjacent to the boundary 120p between two adjacent gate stacking portion (i.e., between a lower gate stacking portion and an upper gate stacking portion), and may be disposed in the lower gate stacking portion. For example, the expanded part 195c may be adjacent to the boundary 120p and may pass through the gate electrode 130 and/or the interlayer insulation layer 132m included in the lower gate stacking portion.

In some implementations, the expanded part 195c may be disposed across a plurality of gate electrodes 130 or a plurality of interlayer insulation layers 132m in the lower gate stacking portion. For example, the expanded part 195c may pass through at least two gate electrodes 130 of the plurality of gate electrodes 130 or at least two interlayer insulation layers 132m of the plurality of interlayer insulation layers 132m. For example, the expanded part 195c may pass through two to twenty gate electrodes 130 or two to twenty interlayer insulation layers 132m. Thereby, the etch stopping pattern may have a sufficient length or depth in the thickness direction of the semiconductor device 10 (the Z-axis direction in the drawings), and the etching may be stopped at a desired position even if there is a process error (an error in an etched depth in the vertical direction). On the other hand, in a comparative implementation in which an etch stopping pattern is disposed in one layer (e.g., one gate electrode or one interlayer insulation layer), a length or a depth of the etch stopping pattern may not be sufficient and etching may be difficult to stop stably. If a thickness of one layer (e.g., one gate electrode or one interlayer insulation layer) increases to prevent the above problem, a number of memory cells may decrease, which may lead to a reduction in data storage capacity.

In some implementations, a width of the expanded part 195c may be greater than a length of the expanded part 195c. The width of the expanded part 195c may refer to a maximum width (e.g., a maximum diameter) of the expanded part 195c or a width of the expanded part 195c at the boundary 120p, and the length of the expanded part 195c may refer to a length (e.g., a maximum length) in the thickness direction of the semiconductor device 10 (the Z-axis direction in the drawings). This may be in consideration of an area of the first through portion P1 or a process error (the position difference in a plan view) in the process of forming the first through portion P1. However, the implementations are not limited thereto. In some implementations, the width of the expanded part 195c may be same or less than the length of the expanded part 195c. Thereby, the etch stopping pattern may have a sufficient length or depth in the thickness direction of the semiconductor device 10 (the Z-axis direction in the drawings), and the etching may be stopped at a desired position even if there is a process error (an error in an etched depth in the vertical direction).

However, the implementations are not limited thereto. The etch stopping pattern may have any of various widths or lengths capable of stably stopping the etching, and the expanded part 195c may have any of various widths or lengths. For example, the width or the length of the etch stopping pattern may be variously modified, considering a width of the first through portion P1, a thickness of each gate stacking portion in the thickness direction of the semiconductor device 10, or the like. According to this, the width or the length of the expanded part 195c may be variously modified.

The first connection contact 193 may include may a base contact (e.g., a first shaped contact 195). The base contact may include a first expanded part 1951c adjacent to the first boundary 121p between the first gate stacking portion 121 and the second gate stacking portion 122 (e.g., the first boundary 121p at the upper portion of the first gate stacking portion 121). The first connection contact 193 may include an additional contact (e.g., a first shaped contact 195). The additional contact may include a second expanded part 1952c adjacent to the second boundary 122p between the second gate stacking portion 122 and the third gate stacking portion 123 (e.g., the second boundary 122p at the upper portion of the second gate stacking portion 122).

With reference to the thirty-sixth gate contact 1936 illustrated in FIG. 4, an example of the first connection contact 193 (e.g., the base contact of the first shaped contact 195) will be described.

In the base contact of the first connection contact 193, the first gate stacking portion 121 may be a lower gate stacking portion, and the second gate stacking portion 122 may be an upper gate stacking portion.

In the base contact of the first connection contact 193, the extension part 195a may include a first extension portion 1951a passing through the second gate stacking portion 122, and a second extension portion 1952a passing through the second stacking portion 120b (e.g., the third gate stacking portion 123). The expanded part 195c may be adjacent to the first boundary 121p between the first gate stacking portion 121 and the second gate stacking portion 122. For example, the expanded part 195c may include the first expanded part 1951c. The first expanded part 1951c may pass through the plurality of first electrodes 1310 or the plurality of interlayer insulation layers 132m in the upper portion of the first gate stacking portion 121. The connection part 195b may pass through a portion of the first gate stacking portion 121 and be electrically connected to the first electrode 1310.

In the additional contact of the first connection contact 193, the second gate stacking portion 122 may be a lower gate stacking portion, and the third gate stacking portion 123 may be an upper gate stacking portion.

In the additional contact of the first connection contact 193, the extension part 195a may include a second extension portion 1952a passing through the second stacking portion 120b (e.g., the third gate stacking portion 123). The expanded part 195c may be adjacent to the second boundary 122p between the second gate stacking portion 122 and the third gate stacking portion 123. For example, the expanded part 195c may include the second expanded part 1952c passing through the plurality of first electrodes 1310 or the plurality of interlayer insulation layers 132m in the upper portion of the second gate stacking portion 122. The connection part 195b may pass through the entirety of the second gate stacking portion 122 and a portion of the first gate stacking portion 121, and be electrically connected to the first electrode 1310 included in the first gate stacking portion 121. For example, the connection part 195b may have an inclined side surface such that a width of the connection part 195b may decrease from an upper portion to a lower portion. The connection part 195b may not include a bent portion at the first boundary 121p.

The additional contact of the first connection contact 193 may have a first shape same as a shape of the base contact of the first connection contact 193, but the expanded part 195c of the additional contact of the first connection contact 193 may include the second expanded part 1952c not the first expanded part 1951c, unlike the base contact of the first connection contact 193. The additional contact of the first connection contact 193 may have the first shape same as a shape of a base contact of the second connection contact 194, but may pass through the entirety of the second gate stacking portion 122 and a portion of the first gate stacking portion 121, and be electrically connected to the first electrode 1310 included in the first gate stacking portion 121, unlike the base contact of the second connection contact 194. For example, the additional contact of the first connection contact 193 may be electrically connected to the first electrode 1310 in the first gate stacking portion 121 that overlaps or corresponds to the first expanded part 1951c of the first connection contact 193 in the thickness direction of the semiconductor device 10 (the Z-axis direction in the drawings). In some implementations, the first expanded part 1951c included in the base contact of the first connection contact 193 may be electrically insulated from the first electrode 1310 in the first gate stacking portion 121 that overlaps or corresponds to the first expanded part 1951c. Accordingly, the additional contact of the first connection contact 193 electrically connected to the first electrode 1310 in the first gate stacking portion 121 that overlaps or corresponds to the first expanded part 1951c may be further included.

The second connection contact 194 may include may a base contact (e.g., second shaped contact 195). The base contact may include a second expanded part 1952c adjacent to the second boundary 122p between the second gate stacking portion 122 and the third gate stacking portion 123 (e.g., the second boundary 122p at the upper portion of the second gate stacking portion 121). The second connection contact 194 may include an additional contact (e.g., a second shaped contact 196) having a shape (e.g., a second shape) different from the first shape.

With reference to the eighteenth gate contact 1918 illustrated in FIG. 5, an example of the second connection contact 194 (e.g., the base contact of the first shaped contact 195) will be described.

In the base contact of the second connection contact 194, the second gate stacking portion 122 may be a lower gate stacking portion, and the third gate stacking portion 123 may be an upper gate stacking portion.

In the base contact of the second connection contact 194, the extension part 195a may include a second extension portion 1952a passing through the second stacking portion 120b (e.g., the third gate stacking portion 123). The expanded part 195c may be adjacent to the second boundary 122p between the second gate stacking portion 122 and the third gate stacking portion 123. For example, the expanded part 195c may include the second expanded part 1952c. The second expanded part 1952c may pass through the plurality of first electrodes 1310 or the plurality of interlayer insulation layers 132m in the upper portion of the second gate stacking portion 122. The connection part 195b may pass through a portion of the second gate stacking portion 122 and be electrically connected to the first electrode 1310.

With reference to the fifteenth gate contact 1915 illustrated in FIG. 6, an example of the second connection contact 194 (e.g., the additional contact of the first shaped contact 195) will be described.

Referring to FIG. 6, the additional contact of the second connection contact 194 may include a connection part (e.g., an additional connection part 196b). The connection part (e.g., the additional connection part 196b) may pass through the second stacking portion 120b and a portion of the first stacking portion 120a, and be electrically connected to the first electrode 1310 included in the first stacking portion 120a. The term of the additional connection part 196b may be used to be discriminated from the connection part 195b of the first shaped contact 195, but the implementations are not limited thereto.

In the additional contact of the second connection contact 194, the additional connection part 196b may pass through the second stacking portion 120b (e.g., the third gate stacking portion 123) and a portion of the first stacking portion 120a (e.g., the second gate stacking portion 122), and be electrically connected to the first electrode 1310 included in the first stacking portion 120a (e.g., the second gate stacking portion 122). For example, the additional connection part 196b may have an inclined side surface such that a width of the additional connection part 196b may decrease from an upper portion to a lower portion. The additional connection part 195b may not include a bent portion at the second boundary 122p. The additional connection part 196b may be disposed in the second through portion P2 formed by the second etching process. For example, the second etching process may include the plurality of partial etching processes using the binary system.

The additional contact of the second connection contact 194 may not include portions corresponding to the extension part 195a and the expanded part 195c of the first shaped contact 195.

The additional contact of the second connection contact 194 may have the second shape different from shapes of the first connection contact 193 and the base contact of the second connection contact 194. The additional contact of the second connection contact 194 may have the second shape same as a shape of the second contact 198, but may pass through the entirety of the third gate stacking portion 123 and a portion of the second gate stacking portion 122 and may be electrically connected to the first electrode 1310 included in the second gate stacking portion 122, unlike the second contact 198. For example, the additional contact of the second connection contact 194 may be electrically connected to the first electrode 1310 in the second gate stacking portion 122 that overlaps or corresponds to the second expanded part 1952c of the second connection contact 194 in the thickness direction of the semiconductor device 10 (the Z-axis direction in the drawings). In some implementations, the second expanded part 1952c included in the base contact of the second connection contact 194 may be electrically insulated from the first electrode 1310 in the second gate stacking portion 122 that overlaps or corresponds to the second expanded part 1952c. Accordingly, the additional contact of the second connection contact 194 electrically connected to the first electrode 1310 in the second gate stacking portion 122 that overlaps or corresponds to the second expanded part 1952c may be further included.

With reference to the twelfth gate contact 1912 illustrated in FIG. 7, the second contact 198 of the second shaped contact 196 will be described.

Referring to FIG. 7, the second contact 198 may include a connection part (e.g., a second connection part 198b). The connection part (e.g., the second connection part 198b) may pass through a portion of the second stacking portion 120b (e.g., the third gate stacking portion 123) and may be electrically connected to the second electrode 1320 included in the second stacking portion 120b. The term of the second connection part 198b may be used to be discriminated from the connection part 195b of the first shaped contact 195, but the implementations are not limited thereto.

In the second contact 198, the second connection part 198b may pass through a portion of the second stacking portion 120b (e.g., the third gate stacking portion 123) and may be electrically connected to the second electrode 1320 included in the second stacking portion 120b (e.g., the third gate stacking portion 123). For example, the second connection part 198b may have an inclined side surface such that a width of the second connection part 198b may decrease from an upper portion to a lower portion. The second connection part 198b may be disposed in the second through portion P2 formed by the second etching process. For example, the second etching process may include the plurality of partial etching processes using the binary system.

The second contact 198 may not include portions corresponding to the extension part 195a and the expanded part 195c of the first shaped contact 195.

The second contact 198 may have the second shape different from shapes of the first connection contact 193 and the base contact of the second connection contact 194. For example, the second contact 198 may be electrically connected to the second electrode 1320 included in the second stacking portion (e.g., the third gate stacking portion 123) that is disposed above the expanded part 195c of the second connection contact 194 in the thickness direction of the semiconductor device 10 (the Z-axis direction in the drawings).

In some implementations, the first shaped contact 195 may include a plurality of first shaped contact 195 having different lengths. The plurality of first shaped contact 195 may be electrically connected to at least a part of the plurality of first electrodes 1310 included in the first stacking portion 120a. The plurality of extension parts 195a included in the plurality of first shaped contacts 195 may have a same length, the plurality of expanded parts 195c included in the plurality of first shaped contacts 195 may have a same length, and the plurality of connection parts 195b in the plurality of first shaped contacts 195 may have different lengths. The length may refer to a length or a depth in the thickness direction of the semiconductor device 10 (the Z-axis direction in the drawings) or in the vertical direction, for example, a maximum length or maximum depth.

That is, in a plurality of first shaped contacts 195 having a plurality of expanded parts 195c adjacent to a same boundary 120p, the plurality of expanded parts 195c adjacent to the same boundary 120p may have a same length, the plurality of extension parts 195a above the plurality of expanded parts 195c may have a same length, and the plurality of connection parts 195b below the plurality of expanded parts 195c may have different lengths. Thereby, the plurality of first shaped contacts 195 may be electrically connected to the plurality of gate electrodes 130, respectively, that are disposed at different heights or levels.

For example, in the plurality of first connection contacts 193 (e.g., the base contacts of the first connection contacts 193) including the first expanded parts 1951c adjacent to the first boundary 121p, the plurality of first expanded parts 1951c may have a same length, the plurality of extension parts 195a (e.g., the plurality of first extension portions 1951a and/or the plurality of second extension portions 1952a) above the plurality of first expanded parts 1951c may have a same length, and the plurality of connection parts 195b below the plurality of first expanded parts 1951c may have different lengths.

For example, in the second connection contacts 194 (e.g., the base contacts of the second connection contacts 194) and/or the additional contact of the first connection contact 193 including the second expanded parts 1952c, the plurality of second expanded parts 1952c adjacent to the second boundary 122p may have a same length, the plurality of extension parts 195a (e.g., the plurality of second extension portions 1952a) above the plurality of second expanded parts 1952c may have a same length, and the plurality of connection parts 195b below the plurality of second expanded parts 1952c may have different lengths.

A lower surface of the expanded part 195c (e.g., a lower surface of the first expanded part 1951c or a lower surface of the second expanded part 1952c) may be a surface that serves as a reference in the second etching process of forming the second through portion P2. By accurately controlling a length or a position of the expanded part 195c in the thickness direction of the semiconductor device 10 or in the vertical direction, the second through portion P2 may be stably formed at a desired position.

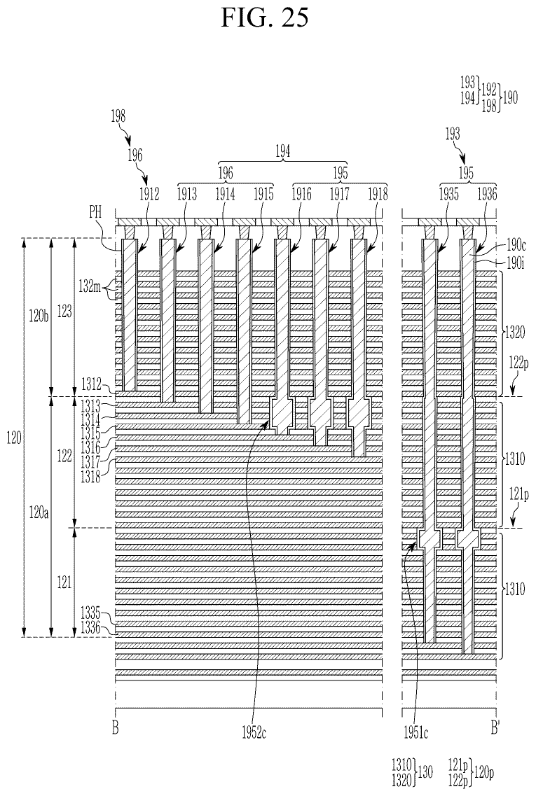

In FIG. 3, it is illustrated as an example that, in the thickness direction of the semiconductor device 10 (the Z-axis direction in the drawings), the first expanded part 1951c adjacent to the first boundary 121p and the second expanded part 1952c adjacent to the second boundary 122p have a same length. Thereby, the first trench corresponding to the first expanded part 1951c and the second trench corresponding to the second expanded part 1952c may be formed using same or similar process condition. Thereby, a manufacturing process may be simplified. However, the implementations are not limited thereto. An implementation will be described later in detail with reference to FIG. 25.

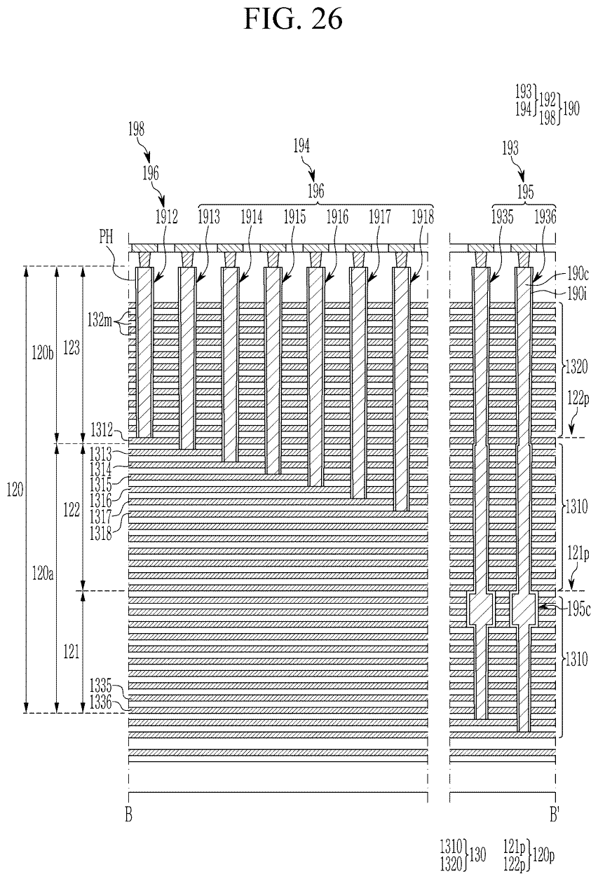

In FIG. 3, it is illustrated as an example that each of the first connection contact 193 and the second connection contact 194 includes the first shaped contact 195 having the first shape. That is, it is illustrated as an example that the expanded parts 195c (e.g., the first expanded part 1951c and the second expanded part 1952c) are disposed at the plurality of boundaries 120p (e.g., the first boundary 121p and the second boundary 122p), respectively. However, the implementations are not limited thereto. In some implementations, at least one of the first connection contact 193 and the second connection contact 194 may not include the first shaped contact 195, and/or the expanded part 195c may be not provided in at least a part of the plurality of boundaries 120p. This will be described in detail with reference to FIG. 26.

In FIG. 1 to FIG. 7, it is illustrated as an example that the gate electrode 130 is disposed in a lower surface of each gate stacking portion (e.g., the first, second, or third gate stacking portion 121, 122, or 123), and the interlayer insulation layer 132m is disposed in an upper surface of each gate stacking portion (e.g., the first, second, or third gate stacking portion 121, 122, or 123). However, the implementations are not limited thereto. In some implementations, the interlayer insulation layer 132m may be disposed in a lower surface of each gate stacking portion (e.g., the first, second, or third gate stacking portion 121, 122, or 123), and/or the gate electrode 130 may be disposed in an upper surface of each gate stacking portion (e.g., the first, second, or third gate stacking portion 121, 122, or 123). In some implementations, the gate electrode 130 may be disposed in at least one of a plurality of lower surfaces of a plurality of gate stacking portions (e.g., the first, second, and third gate stacking portions 121, 122, and 123), and the interlayer insulation layer 132m may be disposed in at least another one of the plurality of lower surfaces of the plurality of gate stacking portion (e.g., the first, second, and third gate stacking portions 121, 122, and 123). The gate electrode 130 may be disposed in at least one of a plurality of upper surfaces of the plurality of gate stacking portions (e.g., the first, second, and third gate stacking portions 121, 122, and 123), and the interlayer insulation layer 132m may be disposed in at least another one of the plurality of upper surfaces of the plurality of gate stacking portions (e.g., the first, second, and third gate stacking portions 121, 122, and 123).

In FIG. 1 to FIG. 7, it is illustrated as an example that each lower surface of the expanded part 195c is disposed on a lower surface of the gate electrode 130, and each upper surface of the expanded part 195c may be disposed on an upper surface of the interlayer insulation layer 132m. In this instance, each lower surface of the etch stopping pattern may be disposed on a lower surface of a sacrificial insulation layer, and each upper surface of the etch stopping pattern may be disposed on an upper surface of the interlayer insulation layer 132m. However, the implementations are not limited thereto. In some implementations, each lower surface of the expanded part 195c or the etch stopping pattern may be disposed on the lower surface of the interlayer insulation layer 132m, and/or each upper surface of the expanded part 195c or the etch stopping pattern may be disposed on the upper surface of the gate electrode 130 or the sacrificial insulation layer. In some implementations, in a plurality of lower surfaces of the plurality of expanded parts 195c (e.g., the first and second expanded parts 1951c and 1952c) or the plurality of etch stopping patterns (e.g., the first and second etch stopping patterns), at least one may be disposed on the lower surface of the gate electrode 130 or the sacrificial insulation layer, and at least another one may be disposed on the lower surface of the interlayer insulation layer 132m. In some implementations, in a plurality of upper surfaces of the plurality of expanded parts 195c (e.g., the first and second expanded parts 1951c and 1952c) or the plurality of etch stopping patterns (e.g., the first and second etch stopping patterns), at least one may be disposed on the upper surface of the gate electrode 130 or the sacrificial insulation layer, and at least another one may be disposed on the upper surface of the interlayer insulation layer 132m. Other various modified implementations are possible.

In some implementations, the expanded part 195c that protrudes horizontally and in which the etch stopping pattern was disposed may be disposed between the extension part 195a and the connection part 195b that are disposed in the first and second through portions P1 and P2, respectively. Thereby, in the first etching process of forming the first through portion P1, the etching may be stably stopped by the etch stopping pattern. The etch stopping pattern may be removed without remaining, and property deterioration that may occur when the etch stopping pattern remains may be prevented.

The first through portion P1 in which the extension part 195a is disposed and the second through portion P2 in which the connection part 195b is disposed may be formed by different etching processes, and a manufacturing process may be simplified. For example, the first through portion P1 may be formed using the high aspect ratio contact etching process of forming the channel through portion, and a manufacturing process of the first through portion P1 may be simplified and a number of the plurality of partial etching processes using the binary system in the second etching process of forming the second through portion P2 may be reduced. The second through portion P2 may have a relatively small length, and the second through portion P2 may be stably formed at a desired position and a structural stability of the connection part 195b in the second through portion P2 may be improved to minimize distortion (e.g., bowing).

Thereby, productivity and reliability of the semiconductor device 10 may be improved.

On the other hand, in a comparative example in which an entire portion of a through hole is formed using a plurality of partial etching processes using a binary system, a number of the plurality of partial etching processes using the binary system may be large and a length of the through hole may be large. Accordingly, the through hole may be difficult to be stably formed at a desired position. For example, the through hole may not be stopped at a desired position, and a structural stability of the through hole may be deteriorated. Accordingly, a manufacturing process may be complicated and reliability may be deteriorated.

In a comparative example in which a gate stacking structure or an insulation stacking structure corresponding to the gate stacking structure includes an etch stopping layer, the etch stopping layer may remain in the gate stacking structure and stability and reliability may be deteriorated. For example, the etch stopping layer includes a semiconductor material or a metallic material for stable etch stopping. When the semiconductor material or the metallic material may remain, an electrical insulation property or the like of a semiconductor device may be deteriorated.

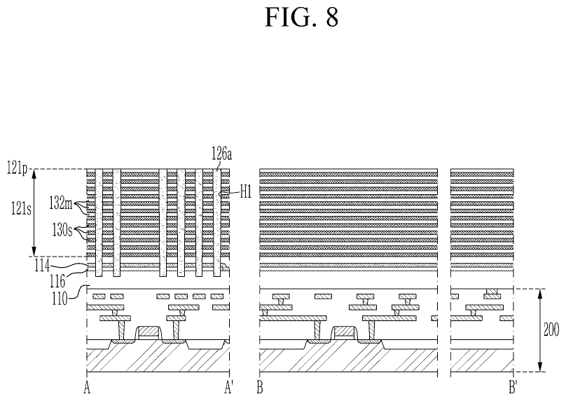

Hereinafter, referring to FIG. 8 to FIG. 20, a manufacturing method of a semiconductor device will be described in detail. To the extent that an element is not described in detail below, it may be understood that the element is at least similar to a corresponding element that has been described elsewhere within the present disclosure. A portion which is not described in the above will be described in detail.

FIGS. 8, 9, 10, 11, 12, 13, 14, 15, 16, 17, 18, 19, and FIG. 20 are partial cross-sectional views illustrating an example of a manufacturing method of a semiconductor device. FIG. 8 to FIG. 20 illustrate a cell array region and a connection region of a cell region illustrated in a portion A-A′ and a portion B-B′ in FIG. 1. In the manufacturing method of the semiconductor device, a gate stacking structure 120, a channel structure CH, a separation structure 146, and a gate contact 190 will be mainly described.

For a clear understanding and simple illustration, in FIG. 8 to FIG. 20, it is illustrated as an example that a first stacking portion includes a first gate stacking portion 121 and a second gate stacking portion 122, a second stacking portion includes the third gate stacking portion 123, and each of the first to third gate stacking portions 121, 122, and 123 includes twelve gate electrodes 130. However, the implementations are not limited thereto, and the first stacking portion may include one gate stacking portion or three or more gate stacking portions, and a number of gate electrodes 130 included in each gate stacking portion may be variously modified.

As illustrated in FIG. 8, a second substrate 110 and a first sacrificial stacking portion 121s may be formed on a circuit region 200, and a first channel sacrificial portion 126a may be formed in a cell array region.

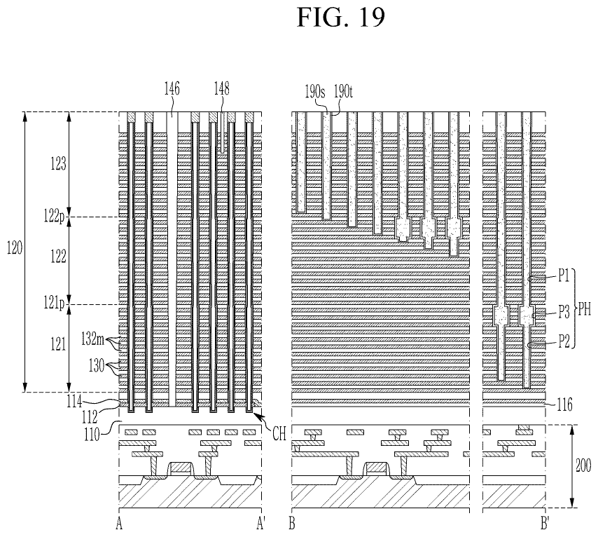

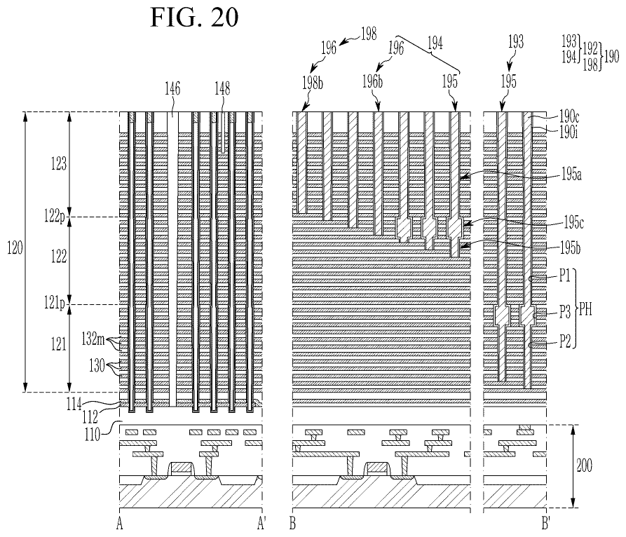

The first sacrificial stacking portion 121s may be a portion corresponding to at least a portion of a first stacking portion. For example, the first sacrificial stacking portion 121s may be a potion corresponding to a first gate stacking portion 121 (refer to FIG. 19) disposed at a lower portion of the first stacking portion. In the first gate stacking portion 121 corresponding to the first sacrificial stacking portion 121s, an expanded part 195c (refer to FIG. 20) (e.g., a first expanded part) of a first shaped contact 195 (refer to FIG. 20) may be disposed, but an extension part 195a (refer to FIG. 20) of the first shaped contact 195 may not be disposed.

For example, the second substrate 110 may be formed on the circuit region 200, a horizontal insulation layer 116 and a second horizontal conductive layer 114 may be formed on the second substrate 110, and the first sacrificial stacking portion 121s may be formed by alternately stacking interlayer insulation layers 132m and sacrificial insulation layers 130s. For example, the first sacrificial stacking portion 121s may be disposed in a cell array region and a connection region, and may include a plurality of sacrificial insulation layers 130s and a plurality of interlayer insulation layers 132m alternately stacked on each other.

The sacrificial insulation layer 130s may be replaced with a gate electrode 130 (refer to FIG. 19) through a subsequent process, and may be formed to correspond to a portion in which the gate electrode 130 will be disposed. At least a portion of the horizontal insulation layer 116 may be replaced with a first horizontal conductive layer 112 (refer to FIG. 19) through a subsequent process, and may be formed to include a portion in which the first horizontal conductive layer 112 will be disposed.

The horizontal insulation layer 116 and/or the sacrificial insulation layer 130s may include a material different from a material of the interlayer insulation layer 132m. For example, the interlayer insulation layer 132m may include or be formed of at least one of silicon oxide, silicon nitride, silicon oxynitride, a low dielectric constant material, or the like. The sacrificial insulation layer 130s may include or be formed of at least one of silicon, silicon oxide, silicon carbide, and silicon nitride, and may include a material different from a material of the interlayer insulation layer 132m.

In the cell array region, the first channel sacrificial portion 126a may be formed to pass through the first sacrificial stacking portion 121s. For example, the first channel sacrificial portion 126a may be formed to pass through the first sacrificial stacking portion 121s, the horizontal insulation layer 116, and the second horizontal conductive layer 114.

For example, a first channel through portion H1 passing through the first sacrificial stacking portion 121s may be formed in a portion in which a channel structure CH (refer to FIG. 19) will be disposed, and a sacrificial material may be formed in the first channel through portion H1 to form the first channel sacrificial portion 126a.

The first channel through portion H1 may be formed by any of various processes (e.g., an etching process or the like). The process of filling the sacrificial material in the first channel through portion H1 may be performed by any of various processes (e.g., a deposition process or the like). The first channel sacrificial portion 126a may include or be formed of a metallic material or a non-metallic material, for example, at least one of polycrystalline silicon, tungsten, titanium nitride, and carbon. However, the implementations are not limited thereto, and the first channel sacrificial portion 126a may include any of various materials.

Subsequently, as illustrated in FIG. 9, a first etch stopping pattern 1951s may be formed in the first sacrificial stacking portion 121s. For example, the first etch stopping pattern 1951s may be formed in an upper portion of the first sacrificial stacking portion 121s adjacent to a first boundary 121p to correspond to a portion where a base contact of a first connection contact 193 (refer to FIG. 20) will be disposed.

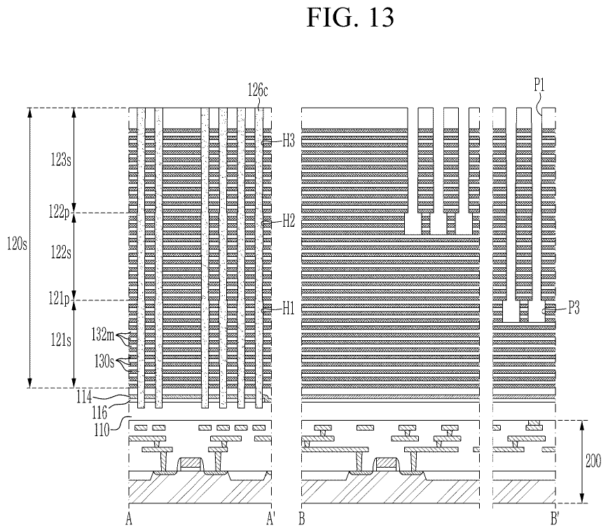

For example, a first trench T1 passing through a portion of the first sacrificial stacking portion 121s may be formed in a portion in which an expanded part 195c (refer to FIG. 20) (e.g., a first expanded part) of the base contact of the first connection contact 193 will be disposed, and a sacrificial material may be filled in the first trench T1 to form the first etch stopping pattern 1951s. The first trench T1 may be a portion corresponding to an expanded through portion P3 (refer to FIG. 13) of the base contact of the first connection contact 193.

The first trench T1 may be formed by any of various processes (e.g., an etching process or the like), and the process of filling the sacrificial material in the first trench T1 may be performed by any of various processes (e.g., a deposition process or the like). The first etch stopping pattern 1951s may include or be formed of a metallic material or a non-metallic material, for example, at least one of polycrystalline silicon, tungsten, titanium nitride, and carbon. However, the implementations are not limited thereto, and the first etch stopping pattern 1951s may include any of various materials. The first etch stopping pattern 1951s may include a material same as a material of the first channel sacrificial portion 126a, or may include a material different from a material of the first channel sacrificial portion 126a.

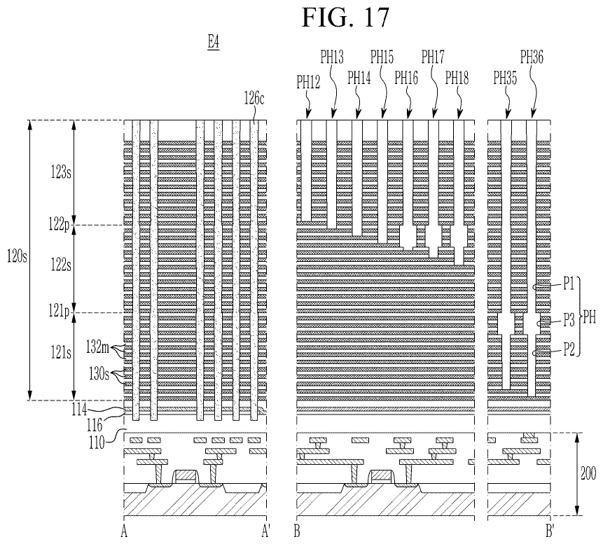

A lower surface of the first trench T1 in which the first etch stopping pattern 1951s is disposed may be a surface that serves as a reference in a second etching process of forming a second through portion P2 (refer to FIG. 17). Therefore, a length or a depth of the first trench T1 may have a predetermined accurate length or depth, or may be accurately controlled to pass through a predetermined number of sacrificial insulation layers 130s or a predetermined number of interlayer insulation layers 132m.

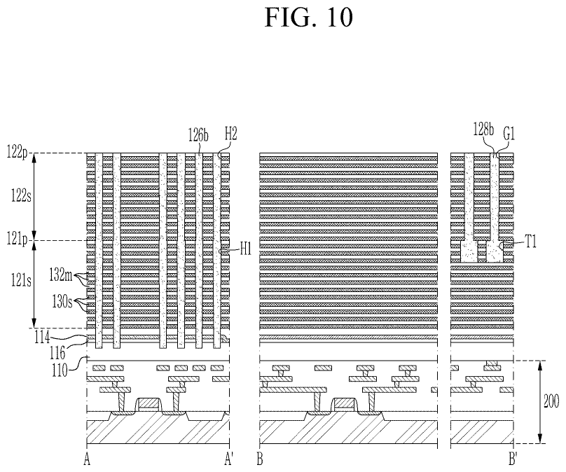

Subsequently, as illustrated in FIG. 10, a second sacrificial stacking portion 122s may be formed on the first sacrificial stacking portion 121s, a second channel sacrificial portion 126b may be formed in the cell array region, and a sacrificial portion 128b may be formed in the connection region.

The second sacrificial stacking portion 122s may be a portion corresponding to at least a portion of the first stacking portion. For example, the second sacrificial stacking portion 122s may be a portion corresponding to a second gate stacking portion 122 (refer to FIG. 19) disposed above the first gate stacking portion 121 in the first stacking portion. In the second gate stacking portion 122 corresponding to the second sacrificial stacking portion 122s, a first extension portion that is a portion of the extension part 195a of the first shaped contact 195 may be disposed, and the expanded part 195c (e.g., a second expanded part) of the first shaped contact 195 may be disposed.

For example, the second sacrificial stacking portion 122s may be formed by alternately stacking interlayer insulation layers 132m and sacrificial insulation layers 130s on the first sacrificial stacking portion 121s. For example, the second sacrificial stacking portion 122s may be disposed in the cell array region and the connection region, and may include a plurality of sacrificial insulation layers 130s and a plurality of interlayer insulation layers 132m alternately stacked on each other.

For example, the interlayer insulation layer 132m may include or be formed of at least one silicon oxide, silicon nitride, silicon oxynitride, a low dielectric constant material, or the like. The sacrificial insulation layer 130s may include or be formed of at least one silicon, silicon oxide, silicon carbide, and silicon nitride, and may include a material different from a material of the interlayer insulation layer 132m.

In the cell array region, the second channel sacrificial portion 126b may be formed to pass through the first sacrificial stacking portion 121s and/or the second sacrificial stacking portion 122s. In the connection region, the sacrificial portion 128b may be formed to pass through the second sacrificial stacking portion 122s.

For example, a second channel through portion H2 passing through the second sacrificial stacking portion 122s may be formed in a portion in which the channel structure CH will be disposed, the first channel sacrificial portion 126a (refer to FIG. 9) may be removed, and a sacrificial material may be filled in the first channel through portion H1 and the second channel through portion H2 to form the second channel sacrificial portion 126b. A first preliminary through portion G1 passing through the second sacrificial stacking portion 122s may be formed in a portion in which the first extension portion of the first shaped contact 195 will be disposed, the first etch stopping pattern 1951s (refer to FIG. 9) may be removed, and a sacrificial material may be filled in the first preliminary through portion G1 and the first trench T1 to form the sacrificial portion 128b.

An etching process of forming the first preliminary through portion G1 may be stopped in the first etch stopping pattern 1951s. That is, after the etching process of forming the first preliminary through portion G1, an end of the first preliminary through portion G1 may be disposed in the first etch stopping pattern 1951s. When the end of the first preliminary through portion G1 is disposed in the first etch stopping pattern 1951s as in the above, a lower surface of the first trench T1 in which the first etch stopping pattern 1951s is disposed may be a surface that serves as a reference in the second etching process of forming the second through portion P2 (refer to FIG. 17), regardless of a position of the end of the first preliminary through portion G1. That is, by the first etch stopping pattern 1951s, the surface that serves as a reference in the second etching process may be accurately controlled.

The second channel through portion H2 may be formed by any of various processes (e.g., an etching process or the like). The process of removing the first channel sacrificial portion 126a may be performed by any of various processes (e.g., an etching process or the like). The process of filling the sacrificial material in the first channel through portion H1 and the second channel through portion H2 may be performed by any of various processes (e.g., a deposition process or the like). The first preliminary through portion G1 may be formed by any of various processes (e.g., an etching process or the like). The process of removing the first etch stopping pattern 1951s may be performed by any of various processes (e.g., an etching process or the like). The process of filling the sacrificial material in the first trench T1 and the first preliminary through portion G1 may be performed by any of various processes (e.g., a deposition process or the like).

For example, the process of forming the second channel through portion H2 and the process of forming the first preliminary through portion G1 may be performed by a same process, the process of removing the first channel sacrificial portion 126a and the process of removing the first etch stopping pattern 1951s may be performed by a same process, and/or the process of filling the sacrificial material in the first and second channel through portions H1 and H2 and the process of filling the sacrificial material in the first trench T1 and the first preliminary through portion G1 may be performed by a same process. Thereby, the second channel sacrificial portion 126b and the sacrificial portion 128b may be formed together, and a manufacturing process may be simplified.

The second channel sacrificial portion 126b or the sacrificial portion 128b may include or be formed of a metallic material or a non-metallic material, for example, at least one of polycrystalline silicon, tungsten, titanium nitride, and carbon. However, the implementations are not limited thereto, and the second channel sacrificial portion 126b or the sacrificial portion 128b may include any of various materials. For example, the second channel sacrificial portion 126b may include a sacrificial material same as a sacrificial material of the sacrificial portion 128b, but the implementations are not limited thereto. For example, the second channel sacrificial portion 126b or the sacrificial portion 128b may include a sacrificial material same as a sacrificial material of the first channel sacrificial portion 126a, or may include a sacrificial material different from the sacrificial material of the first channel sacrificial portion 126a.

In the description, it is described as an example that the first channel sacrificial portion 126a is removed and thereafter the second channel sacrificial portion 126b is formed, and the first etch stopping pattern 1951s is removed and thereafter the sacrificial portion 128b is formed. However, the implementations are not limited thereto. In some implementations, in a state that at least a portion of the first channel sacrificial portion 126a and/or the first etch stopping pattern 1951s remains, the second channel sacrificial portion 126b and/or the sacrificial portion 128b may be formed.

Subsequently, as illustrated in FIG. 11, a second etch stopping pattern 1952s may be formed in the second sacrificial stacking portion 122s. For example, the second etch stopping pattern 1952s may be formed in an upper portion of the second sacrificial stacking portion 122s adjacent to a second boundary 122p to correspond to a portion in which a base contact of a second connection contact 194 (refer to FIG. 20) and/or an additional contact of the first connection contact 193 will be disposed.

For example, a second trench T2 passing through a portion of the second sacrificial stacking portion 122s may be formed in a portion in which the expanded part 195c (e.g., a second expanded part) of the base contact of the second connection contact 194 and/or the additional contact of the first connection contact 193 will be disposed, and a sacrificial material may be filled in the second trench T2 to form the second etch stopping pattern 1952s. The second trench T2 may be a portion corresponding to the expanded through portion P3 of the base contact of the second connection contact 194 and/or the additional contact of the first connection contact 193.

The second trench T2 may be formed by any of various processes (e.g., an etching process or the like). The process of filling the sacrificial material in the second trench T2 may be performed by any of various processes (e.g., a deposition process or the like). The second etch stopping pattern 1952s may include or be formed of a metallic material or a non-metallic material, for example, at least one of polycrystalline silicon, tungsten, titanium nitride, and carbon. However, the implementations are not limited thereto, and the second etch stopping pattern 1952s may include any of various materials. The second etch stopping pattern 1952s may include a material same as a material of the first etch stopping pattern 1951s, the first channel sacrificial portion 126a, the second channel sacrificial portion 126b, and/or the sacrificial portion 128b, or may include a material different from a material of the first etch stopping pattern 1951s, the first channel sacrificial portion 126a, the second channel sacrificial portion 126b, and/or the sacrificial portion 128b.

A lower surface of the second trench T2 in which the second etch stopping pattern 1952s is disposed may be the surface that serves as a reference in the second etching process of forming the second through portion P2 (refer to FIG. 17). Therefore, a length or a depth of the second trench T2 may have a predetermined accurate length or depth, or may be accurately controlled to pass through a predetermined number of sacrificial insulation layers 130s or a predetermined number of interlayer insulation layers 132m.

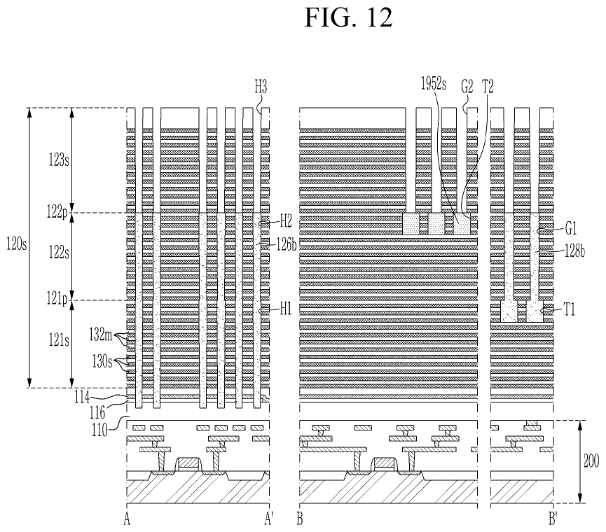

Subsequently, as illustrated in FIG. 12, a third sacrificial stacking portion 123s may be formed on the second sacrificial stacking portion 122s to form a stacking structure 120s, a third channel through portion H3 may be formed in the cell array region, and a second preliminary through portion G2 may be formed in the connection region.

The third sacrificial stacking portion 123s may be a portion corresponding to a second stacking portion. For example, the third sacrificial stacking portion 123s may be a portion corresponding to a third gate stacking portion 123 (refer to FIG. 19) disposed in an upper portion of the plurality of stacking portions. In the third gate stacking portion 123 corresponding to the third sacrificial stacking portion 123s, a second extension portion that is a portion of the extension part 195a of the first shaped contact 195 may be disposed.

For example, the third sacrificial stacking portion 123s may be formed by alternately stacking interlayer insulation layers 132m and sacrificial insulation layers 130s on the second sacrificial stacking portion 122s. For example, the third sacrificial stacking portion 123s may be disposed in the cell array region and the connection region, and may include a plurality of sacrificial insulation layers 130s and a plurality of interlayer insulation layers 132m alternately stacked on each other.

For example, the interlayer insulation layer 132m may include or be formed of at least one silicon oxide, silicon nitride, silicon oxynitride, a low dielectric constant material, or the like. The sacrificial insulation layer 130s may include or be formed of at least one silicon, silicon oxide, silicon carbide, and silicon nitride, and may include a material different from a material of the interlayer insulation layer 132m.

In the cell array region, a third channel through portion H3 may be formed to pass through the third sacrificial stacking portion 123s. In the connection region, the second preliminary through portion G2 may be formed to pass through the third sacrificial stacking portion 123s.

For example, the third channel through portion H3 passing through the third sacrificial stacking portion 123s may be formed in a portion in which the channel structure CH will be disposed. The second preliminary through portions G2 passing through the third sacrificial stacking portion 123s may be formed in portions in which a second extension portion of the first connection contact 193 and a second extension portion of the second connection contact 194 will be disposed.

An etching process of forming the second preliminary through portion G2 of the second connection contact 194 may be stopped in the second etch stopping pattern 1952s. That is, after the etching process of forming the second preliminary through portion G2 of the second connection contact 194, an end of the second preliminary through portion G2 of the second connection contact 194 may be disposed in the second etch stopping pattern 1952s. When the end of the second preliminary through portion G2 is disposed in the second etch stopping pattern 1952s as in the above, a lower surface of the second trench T2 in which the second etch stopping pattern 1952s is disposed may be a surface that serves as a reference in the second etching process of forming the second through portion P2 (refer to FIG. 17), regardless of a position of the end of the second preliminary through portion G2. That is, by the second etch stopping pattern 1952s, the surface that serves as a reference in the second etching process may be accurately controlled.

The third channel through portion H3 may be formed by any of various processes (e.g., an etching process or the like). The second preliminary through portion G2 may be formed by any of various processes (e.g., an etching process or the like). For example, the process of forming the third channel through portion H3 and the process of forming the second preliminary through portion G2 may be performed by a same process. Thereby, a manufacturing process may be simplified.

Subsequently, as illustrated in FIG. 13, a third channel sacrificial portion 126c may be formed by filling a sacrificial material in the third channel through portion H3. A first through portion P1 and an expanded through portion P3 may be formed by removing the second etch stopping pattern 1952s (refer to FIG. 12) and the sacrificial portion 128b (refer to FIG. 12).

For example, the second channel sacrificial portion 126b may be removed, and the third channel sacrificial portion 126c may be formed by filling the sacrificial material in the first channel through portion H1, the second channel through portion H2, and the third channel through portion H3.

The process of filling the sacrificial material in the first channel through portion H1, the second channel through portion H2, and the third channel through portion H3 may be performed by any of various processes (e.g., a deposition process or the like). The third channel sacrificial portion 126c may include or be formed of a metallic material or a non-metallic material, for example, at least one of polycrystalline silicon, tungsten, titanium nitride, and carbon. However, the implementations are not limited thereto, and the third channel sacrificial portion 126c may include any of various materials.

The process of removing the second etch stopping pattern 1952s and the sacrificial portion 128b may be performed by any of various processes (e.g., an etching process or the like).

The process of forming the first preliminary through portion G1 illustrated in FIG. 10 and the process of forming the second preliminary through portion G2 illustrated in FIG. 12 may be a first etching process of forming the first through portion P1. The first etching process may be a high aspect ratio contact etching process that etches the entirety of one sacrificial stacking portion, and may be performed in the process of forming the second channel through portion H2 or the third channel through portion H3.

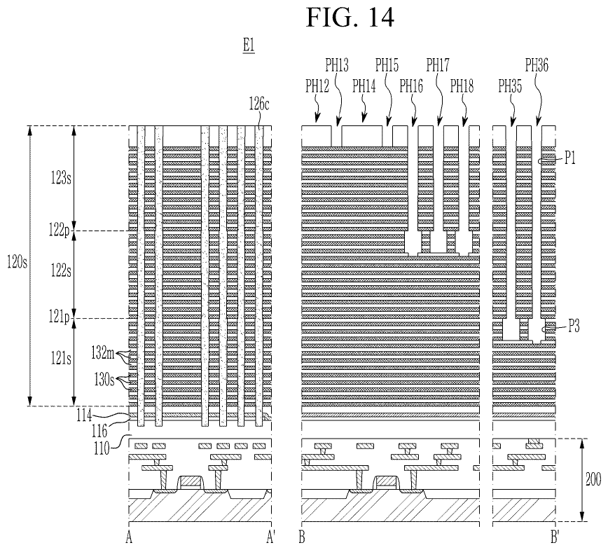

Subsequently, as illustrated FIG. 14 to in FIG. 17, a through hole PH may be formed by forming a second through portion P2 through the first through portion P1 and the expanded through portion P3. For example, the second through portion P2 may be formed by performing a second etching process different from the first etching process. In the second etching process, a plurality of second through portions P2 of a plurality of through holes PH may be formed using the plurality of partial etching processes (e.g., first to fourth partial etching processes E1, E2, E3, and E4) using a binary system.

For a clear understanding and simple illustration, in FIG. 14 to FIG. 17, it is illustrated as an example that each gate stacking portion includes twelve sacrificial insulation layers 130s, and first to fourth partial etching processes E1, E2, E3, and E4 are performed. For a clear understanding, FIG. 14 to FIG. 17 illustrate positions of twelfth to eighteenth through holes PH12 to PH18 corresponding to twelfth to eighteenth gate contacts, respectively, and thirty-fifth and thirty-sixth through holes PH35 and PH36 corresponding to thirty-fifth and thirty-sixth gate contacts, respectively. However, the implementations are not limited thereto, and a number of the sacrificial insulation layers 130s included in each gate stacking portion may be variously modified, and a number of partial etching processes may be variously modified according to the number of the sacrificial insulation layers 130s.

In some implementations, a position (e.g., a position or a level in a vertical direction) of the sacrificial insulation layer 130s to be replaced with the gate electrode 130 may be converted to a binary system. According thereto, a plurality of partial etching processes (e.g., first to fourth partial etching processes E1, E2, E3, and E4) may be performed to form a plurality of second through portions P2 of a plurality of through holes PH having different depths. After the first to fourth partial etching processes E1, E2, E3, and E4, an additional partial etching process may be further performed.

In a through hole among the plurality of through holes PH that does not include the first through portion P1 and the expanded through portion P3, a position of the sacrificial insulation layer 130s may be a position from an upper surface of the stacking structure 120s. In a through hole among the plurality of through holes PH that includes the first through portion P1 and the expanded through portion P3, a position of the sacrificial insulation layer 130s may be a position from a lower surface of the expanded through portion P3.

The plurality of partial etching processes (e.g., the first to fourth partial etching processes E1, E2, E3, and E4) may be cyclic etching processes. In each partial etching process, a mask configured to expose a predetermined portion may be formed, the partial etching process according to the binary system may be performed, and the mask may be removed. In the additional partial etching process, a mask configured to expose a predetermined portion may be formed, an etching process according to the binary system or a sequential etching process may be performed, and the mask may be removed. The mask may be a photoresist layer or a hard mask layer including or formed of a photosensitivity material. In the first to fourth partial etching processes E1, E2, E3, and E4 and/or the additional partial etching process, the process of etching the stacking structure 120s may be performed by any of various etching processes (e.g., a dry etching process or the like).

For example, in the plurality of partial etching processes (e.g., the first to fourth partial etching processes E1, E2, E3, and E4) using the binary system, an interlayer insulation layer 132m or a sacrificial insulation layer 130s of a number of 1, 2, 4, . . . , 2⁽ⁿ⁻1) may be etched according to the binary system.

In some implementations, in a gate contact 190 (refer to FIG. 20) (e.g., first to eleventh gate contacts, a twelfth gate contact 1912 (refer to FIG. 3), a thirteenth gate contact 1913 (refer to FIG. 3), a fourteenth gate contact 1914 (refer to FIG. 3), a fifteenth gate contact 1915 (refer to FIG. 3)) including the second through portion P2 without the first through portion P1 and the expanded through portion P3, a position of a sacrificial insulation layer 130s corresponding to each gate electrode 130 may be a position from an upper surface of the stacking structure 120s.

For example, a position (i.e., 12) of a sacrificial insulation layer 130s (e.g., a twelfth sacrificial insulation layer) corresponding to the twelfth gate contact 1912 electrically connected to the twelfth gate contact may be converted to 1100 according to the binary system, and a second through portion P2 of a twelfth through hole PH12 reaching the twelfth sacrificial insulation layer may be formed by performing the third partial etching process E3 and the fourth partial etching process E4.

For example, a position (i.e., 13) of a sacrificial insulation layer 130s (e.g., a thirteenth sacrificial insulation layer) corresponding to a thirteenth gate electrode electrically connected to the thirteenth gate contact 1913 may be converted to 1101 according to the binary system, and a second through portion P2 of a thirteenth through hole PH13 reaching the thirteenth sacrificial insulation layer may be formed by performing the first partial etching process E1, the third partial etching process E3, and the fourth partial etching process E4. For example, a position (i.e., 14) of a sacrificial insulation layer 130s (e.g., a fourteenth sacrificial insulation layer) corresponding to a fourteenth gate electrode electrically connected to the fourteenth gate contact 1914 may be converted to 1110 according to the binary system, and a second through portion P2 of a fourteenth through hole PH14 reaching the fourteenth sacrificial insulation layer may be formed by performing the second partial etching process E2, the third partial etching process E3, and the fourth partial etching process E4. For example, a position (i.e., 15) of a sacrificial insulation layer 130s (e.g., a fifteenth sacrificial insulation layer) corresponding to the fifteenth gate contact 1915 electrically connected to the fifteenth gate contact may be converted to 1111 according to the binary system, and a second through portion P2 of a fifteenth through hole PH15 reaching the fifteenth sacrificial insulation layer may be formed by performing the first partial etching process E1, the second partial etching process E2, the third partial etching process E3, and the fourth partial etching process E4.

In some implementations, in a gate contact 190 (e.g., a sixteenth gate contact 1916 (refer to FIG. 3), a seventeenth gate contact 1917 (refer to FIG. 3), an eighteenth gate contact 1918 (refer to FIG. 3), a nineteenth gate contact to a thirty-fourth gate contact, a thirty-fifth gate contact 1935 (refer to FIG. 3), or a thirty-sixth gate contact 1936 (refer to FIG. 3)) including the second through portion P2 extended from the expanded through portion P3, a position of a sacrificial insulation layer 130s corresponding each gate electrode 130 may be a position from a lower surface of the expanded through portion P3.

For example, a sacrificial insulation layer 130s (e.g., a sixteenth sacrificial insulation layer) corresponding to a sixteenth gate electrode electrically connected to the sixteenth gate contact 1916 may be spaced apart from an expanded through portion P3 while interposing one interlayer insulation layer 132m therebetween, and a position of the sixteenth sacrificial insulation layer may be 1. A position (i.e., 1) of the sixteenth sacrificial insulation layer may be converted to 1 according to the binary system, and a second through portion P2 of a sixteenth through hole PH16 reaching the sixteenth sacrificial insulation layer may be formed by performing the first partial etching process E1. For example, a position (i.e., 2) of a sacrificial insulation layer 130s (e.g., a seventeenth sacrificial insulation layer) corresponding to a seventeenth gate electrode electrically connected to the seventeenth gate contact 1917 may be converted to 10 according to the binary system, and a second through portion P2 of a seventeenth through hole PH17 reaching the seventeenth sacrificial insulation layer may be formed by performing the second partial etching process E2. For example, a position (i.e., 3) of a sacrificial insulation layer 130s (e.g., an eighteenth sacrificial insulation layer) corresponding to an eighteenth gate electrode electrically connected to the eighteenth gate contact 1918 may be converted to 11 according to the binary system, and a second through portion P2 of an eighteenth through hole PH18 reaching the eighteenth sacrificial insulation layer may be formed by performing the first partial etching process E1 and the second partial etching process E2.

For example, a sacrificial insulation layer 130s (e.g., a thirty-fifth sacrificial insulation layer) corresponding to the thirty-fifth gate contact 1935 electrically connected to the thirty-fifth gate contact 1935 may be spaced apart from an expanded through portion P3 while interposing eight interlayer insulation layers 132m therebetween, and a position of the thirty-fifth sacrificial insulation layer may be 8. A position (i.e., 8) of the thirty-fifth sacrificial insulation layer may be converted to 1000 according to the binary system, and a second through portion P2 of a thirty-fifth through hole PH35 reaching the thirty-fifth sacrificial insulation layer may be formed by performing the fourth partial etching process E4. For example, a position (i.e., 9) of a sacrificial insulation layer 130s (e.g., a thirty-sixth sacrificial insulation layer) corresponding to a thirty-sixth gate electrode electrically connected to the thirty-sixth gate contact 1936 may be converted to 1001 according to the binary system, and a second through portion P2 of a thirty-sixth through hole PH36 reaching the thirty-sixth sacrificial insulation layer may be formed by performing the first partial etching process E1 and the fourth partial etching process E4.

Hereinafter, referring to FIG. 14 to FIG. 17, a process of forming the plurality of second through portions P2 of the plurality of through holes PH will be described in more detail based on the second through portions P2 of the twelfth to eighteenth through holes PH12 to PH18, the thirty-fifth through hole PH35, and the thirty-sixth through hole PH36.

As illustrated in FIG. 14, in the first partial etching process E1, portions of the plurality of through holes PH that correspond to the first partial etching process E1 may be selectively etched. For example, in the first partial etching process E1, in portions that correspond to the thirteenth through hole PH13, the fifteenth through hole PH15, the sixteenth through hole PH16, the eighteenth through hole PH18, and the thirty-sixth through hole PH36, one interlayer insulation layer 132m may be etched.

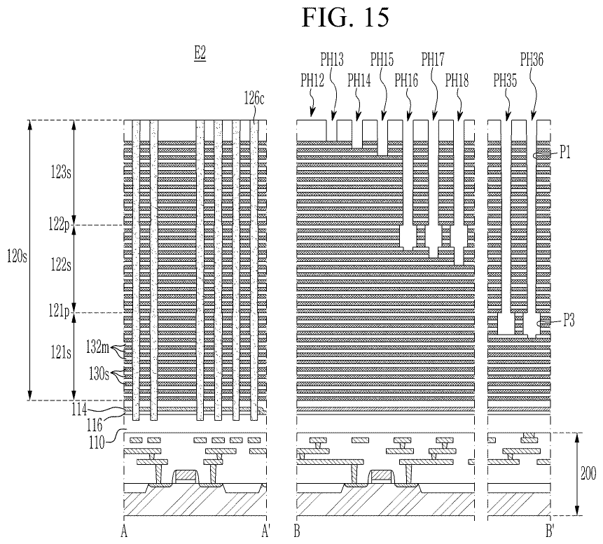

Subsequently, as illustrated in FIG. 15, in the second partial etching process E2, portions of the plurality of through holes PH that correspond to the second partial etching process E2 may be selectively etched. For example, in the second partial etching process E2, in portions that correspond to the fourteenth through hole PH14, the fifteenth through hole PH15, the seventeenth through hole PH17, and the eighteenth through hole PH18, two interlayer insulation layers 132m and sacrificial insulation layers 130s thereon may be etched.

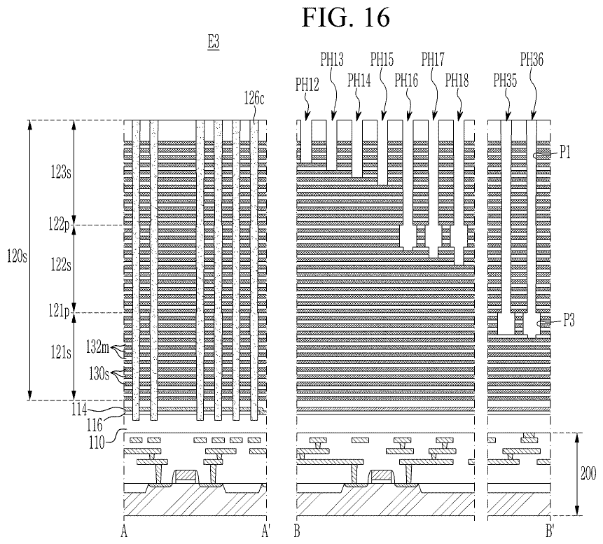

Subsequently, as illustrated in FIG. 16, in the third partial etching process E3, portions of the plurality of through holes PH that correspond to the third partial etching process E3 may be selectively etched. For example, in the third partial etching process E3, in portions that correspond to the twelfth through hole PH12, the thirteenth through hole PH13, the fourteenth through hole PH14, and the fifteenth through hole PH15, four sacrificial insulation layers 130s and sacrificial insulation layers 130s thereon may be etched.

Subsequently, as illustrated in FIG. 17, in the fourth partial etching process E4, portions of the plurality of through holes PH that correspond to the fourth partial etching process E4 may be selectively etched. For example, in the fourth partial etching process E4, in portions that correspond to the twelfth through hole PH12, the thirteenth through hole PH13, the fourteenth through hole PH14, the fifteenth through hole PH15, the thirty-fifth through hole PH35, and the thirty-sixth through hole PH36, eight sacrificial insulation layers 130s and sacrificial insulation layers 130s thereon may be etched.

However, the implementations are not limited to the second etching process, and the partial etching processes using the binary system may be variously modified.

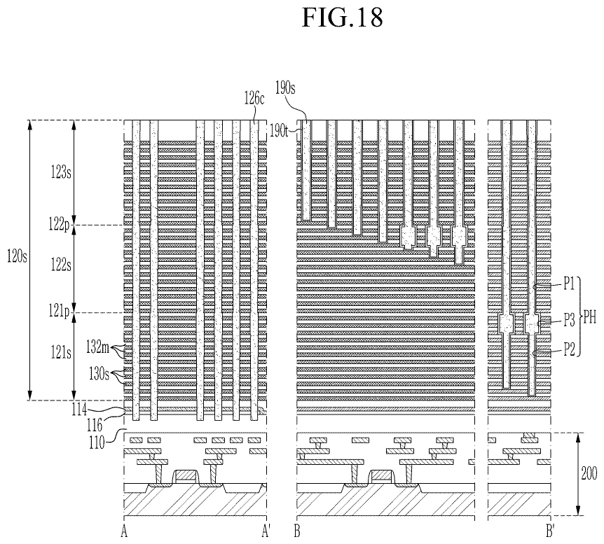

Subsequently, as illustrated in FIG. 18, a protective insulation layer 190t and a penetration sacrificial layer 190s may be formed in each of the plurality of through holes PH.

The protective insulation layer 190t may be disposed in each of the plurality of through holes PH. For example, the protective insulation layer 190t may be formed on an inner side surface and a lower surface in each of the plurality of through holes PH. The process of forming the protective insulation layer 190t may be performed by any of various processes (e.g., a deposition process or the like). However, the implementations are not limited thereto.

After the protective insulation layer 190t is formed, the penetration sacrificial layer 190s may be formed on the protective insulation layer 190t in each of the plurality of through holes PH. The penetration sacrificial layer 190s may include or be formed of a metallic material or a non-metallic material, for example, at least one of polycrystalline silicon, tungsten, titanium nitride, and carbon. However, the implementations are not limited thereto, and the penetration sacrificial layer 190s may include any of various materials.

Subsequently, as illustrated in FIG. 19, a channel structure CH, a gate electrode 130, and a separation structure 146 may be formed.

For example, a channel through portion may be formed by removing the third channel sacrificial portion 126c (refer to FIG. 18). A process of forming the channel through portion may be performed by any of various processes (e.g., an etching process or the like). In some implementations, in the channel through portion, a gate dielectric layer 150 (refer to FIG. 2), a channel layer 140 (refer to FIG. 2), and a core insulation layer 142 (refer to FIG. 2) may be sequentially formed, and a channel pad 144 (refer to FIG. 2) may be formed. The processes of forming the gate dielectric layer 150, the channel layer 140, the core insulation layer 142, or the channel pad 144 may be performed by any of various processes (e.g., a deposition process or the like).

An opening for a separation structure that passes through the insulation stacking structure 120s (refer to FIG. 18) may be formed in an area corresponding to the separation structure 146, the sacrificial insulation layers 130s (refer to FIG. 18) may be replaced with gate electrodes 130, and the opening for the separation structure may be filled with an insulating material or the like to form the separation structure 146.

In some implementations, the opening for the separation structure may be formed by an etching process (e.g., a dry etching process or the like). The sacrificial insulation layers 130s may be selectively removed by an etching process (e.g., a wet etching process) through the opening for the separation structure. The gate electrodes 130 may be formed by filling portions from which the sacrificial insulation layers 130s were removed with a conductive material. As a result, areas where the sacrificial insulation layers 130s were disposed may be replaced with the gate electrodes 130. In this instance, a process of forming a portion of a blocking layer 156 (refer to FIG. 2) (for example, a first blocking layer 156a (refer to FIG. 2)) may be further performed before the process of filing the conductive material constituting the gate electrodes 130. However, the implementations are not limited thereto. The process of filling the material in the opening for the separation structure may be performed by any of various processes (e.g., a deposition process or the like).

In some implementations, the opening for the separation structure may expose the horizontal insulation layer 116 (refer to FIG. 18). In the etching process through the opening for the separation structure, at least a portion of the horizontal insulation layer 116 and at least a portion of the gate dielectric layer 150 may be removed, and a material of a first horizontal conductive layer 112 may be filled. Thereby, the first horizontal conductive layer 112 may be formed.

In some implementations, an upper separation region 148 may be formed in a portion of the stacking structure 120s or the gate stacking structure 120. The upper separation region 148 may be formed by forming an opening for a separation pattern through an etching process using a mask layer and filling an insulating material to at least a portion of the opening for the separation pattern. The process of forming the opening for the separation pattern may be performed by any of various etching processes (e.g., a dry etching process). The process filling the insulating material in the opening for the separation pattern may be performed by any of various processes (e.g., a deposition process or the like). An order of the process of forming the opening for the separation pattern and the process filling the insulating material in the opening for the separation pattern may be variously modified.

Subsequently, as illustrated in FIG. 20, a side insulation layer 190i may be formed by removing the penetration sacrificial layer 190s (refer to FIG. 19), and removing a lower portion of the protective insulation layer 190t (refer to FIG. 19) (i.e., a portion on an upper surface of the gate electrode 130). The conductive portion 190c may be formed by filling a conductive material in the through hole PH. Accordingly, the gate contact 190 may be formed.

The process of removing the penetration sacrificial layer 190s may be performed by any of various processes (e.g., an etching process or the like). The process of removing the lower portion of the protective insulation layer 190i may be performed by any of various processes (e.g., an etching process or the like). The process of forming the conductive portion 190c may be performed by any of various processes (e.g., a deposition process or the like).

Subsequently, a cell wiring portion (e.g., a bit line or the like) connected to the channel structure CH may be formed to form a semiconductor device illustrated in FIG. 1.

In some implementations, in the etching process of forming the first through portion P1, the etching may be stably stopped by the etch stopping pattern (e.g., the first etch stopping pattern 1951s and/or the second etch stopping pattern 1952s). The etch stopping pattern may be removed without remaining, and property deterioration that may occur when the etch stopping pattern remains may be prevented.

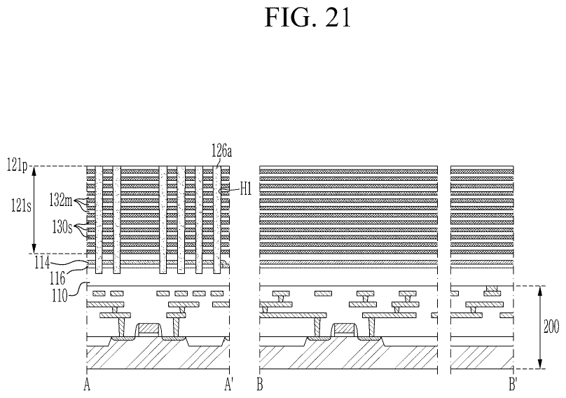

Hereinafter, referring to FIG. 21 to FIG. 24, semiconductor devices and manufacturing methods thereof according to implementations will be described in more detail. To the extent that an element is not described in detail below, it may be understood that the element is at least similar to a corresponding element that has been described elsewhere within the present disclosure. A portion which is not described in the above will be described in detail.

FIGS. 21, 22, 23, and FIG. 24 are partial cross-sectional views illustrating an example of a manufacturing method of a semiconductor device. FIG. 21 to FIG. 24 illustrate a cell array region and a connection region of a cell region corresponding to a portion A-A′ and a portion B-B′ in FIG. 1. In the manufacturing method of the semiconductor device, a gate stacking structure 120 (refer to FIG. 19), a channel structure CH (refer to FIG. 19), a separation structure 146 (refer to FIG. 19), and a gate contact 190 (refer to FIG. 20) will be mainly described.

For a clear understanding and simple illustration, in FIG. 21 to FIG. 24, it is illustrated as an example that a first stacking portion includes a first gate stacking portion 121 and a second gate stacking portion 122, a second stacking portion includes a third gate stacking portion 123, and each of the first to third gate stacking portions 121, 122, and 123 includes twelve gate electrodes 130. However, the implementations are not limited thereto, and the first stacking portion may include one gate stacking portion or three or more gate stacking portions, and a number of gate electrodes 130 included in each gate stacking portion may be variously modified.

As illustrated in FIG. 21, a second substrate 110 and a first sacrificial stacking portion 121s may be formed on a circuit region 200, and a first channel sacrificial portion 126a may be formed in a cell array region. A description with reference to FIG. 8 may be applied.

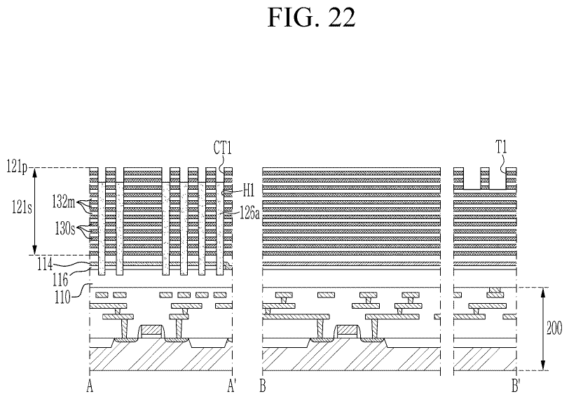

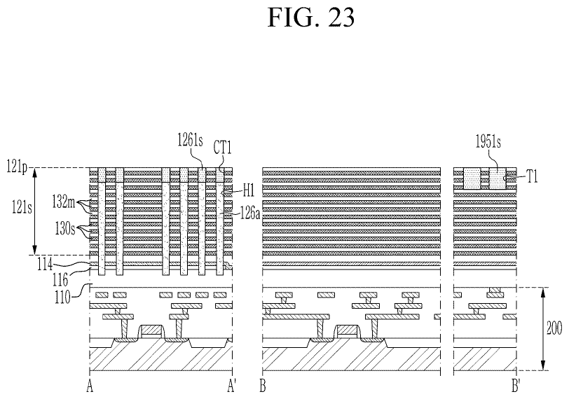

Subsequently, as illustrated in FIG. 22, a first trench T1 may be formed in a portion of the first sacrificial stacking portion 121s in which a first etch stopping pattern 1951s (refer to FIG. 23) will be disposed. For example, the first trench T1 passing through a portion of the first sacrificial stacking portion 121s may be formed in a portion in which an expanded part 195c (refer to FIG. 20) (e.g., a first expanded part) of a base contact of a first connection contact 193 (refer to FIG. 25) will be disposed.

In some implementations, a portion (e.g., an upper portion) of the first channel sacrificial portion 126a may be removed together in the process of forming the first trench T1, and a first removed portion CT1 may be formed. However, the implementations are not limited thereto, and a process of forming the first removed portion CT1 may be performed before or after the process of forming the first trench T1. The process of forming the first trench T1 and/or the process of forming the first removed portion CT1 may be performed by any of various processes (e.g., an etching process or the like).

In a thickness direction (a Z-axis direction in the drawings) of the first sacrificial stacking portion 121s, a length or a depth of the first trench T1 may be same as or different from a length or a depth of the first removed portion CT1.

Subsequently, as illustrated in FIG. 23, a first plug 1261s and a first etch stopping pattern 1951s may be formed by filling a sacrificial material in the first removed portion CT1 and the first trench T1.

The process of filling the sacrificial material in the first removed portion CT1 and the first trench T1 may be performed by any of various processes (e.g., a deposition process or the like). The first plug 1261s or the first etch stopping pattern 1951s may include or be formed of a metallic material or a non-metallic material, for example, at least one of polycrystalline silicon, tungsten, titanium nitride, and carbon. However, the implementations are not limited thereto, and the first plug 1261s or the first etch stopping pattern 1951s may include any of various materials. The first plug 1261s or the first etch stopping pattern 1951s may include a material different from a material of the first channel sacrificial portion 126a. For example, the first plug 1261s may include a material having hardness greater than hardness of a material of the first channel sacrificial portion 126a. However, the implementations are not limited thereto, and the first plug 1261s or the first etch stopping pattern 1951s may include a material same as a material of the first channel sacrificial portion 126a.

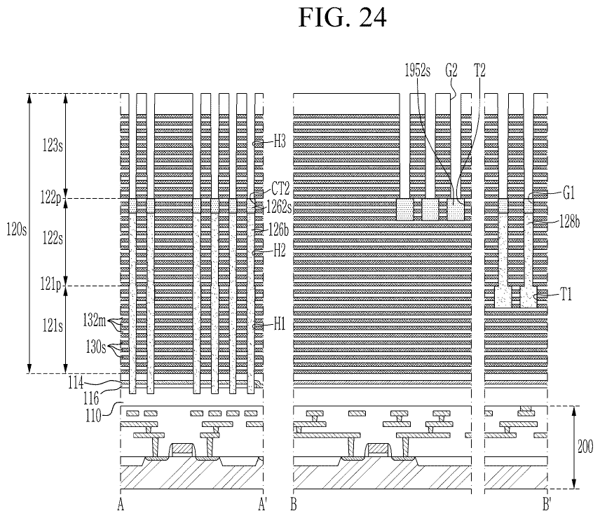

Subsequently, as illustrated in FIG. 24, a second sacrificial stacking portion 122s may be formed on the first sacrificial stacking portion 121s, a second channel sacrificial portion 126b may be formed in a cell array region, and a sacrificial portion 128b may be formed in a connection region. Unless otherwise described, a description with reference to FIG. 10 may be applied.

For example, a second channel through portion H2 passing through the second sacrificial stacking portion 122s may be formed in a portion in which a channel structure CH will be disposed, the first channel sacrificial portion 126b (refer to FIG. 23) and the first plug 1261s (refer to FIG. 23) may be removed, and a sacrificial material may be filled in the first channel through portion H1 and the second channel through portion H2 to form the second channel sacrificial portion 126b. A first preliminary through portion G1 passing through the second sacrificial stacking portion 122s may be formed in a portion in which a first extension portion of a first shaped contact will be disposed, the first etch stopping pattern 1951s (refer to FIG. 23) may be removed, and a sacrificial material may be filled in the first preliminary through portion G1 and the first trench T1 to form the sacrificial portion 128b.

The etching process of forming the first preliminary through portion G1 may be stopped in the first etch stopping pattern 1951s, and the etching process of forming the second channel through portion H2 may be stopped in the first plug 1261s. Accordingly, in the etching process of forming the first preliminary through portion G1 and/or the second channel through portion H2, the etching may be stably stopped in the first etch stopping pattern 1951s and/or the first plug 1261s.

A second trench T2 may be formed in a portion of the second sacrificial stacking portion 122s in which a second etch stopping pattern 1952s will be disposed. For example, the second trench T2 passing through a portion of the second sacrificial stacking portion 122s may be formed in a portion in which the expanded part 195c (e.g., a second expanded part) of a base contact of a second connection contact 194 and/or an additional contact of the first connection contact 193 will be formed.

In some implementations, a portion (e.g., an upper portion) of the second channel sacrificial portion 126b may be removed together in the process of forming the second trench T2, and a second removed portion CT2 may be formed. A portion (e.g., an upper portion) of the sacrificial portion 128a may be removed together in the process of forming the second trench T2, and an additional removed portion may be formed. However, the implementations are not limited thereto, and a process of forming the second removed portion CT2 or the additional removed portion may be performed before or after the process of forming the second trench T2. The process of forming the second trench T2 and/or the process of forming the second removed portion CT2 and/or the additional removed portion may be performed by any of various processes (e.g., an etching process or the like).

In a thickness direction (a Z-axis direction in the drawings) of the second sacrificial stacking portion 122s, a length or a depth of the second trench T2 may be same as or different from a length or a depth of the second removed portion CT2 or the additional removed portion.

A second plug 1262s and a second etch stopping pattern 1952s may be formed by filling a sacrificial material in the second removed portion CT2 and the second trench T2. An additional plug may be further formed by filling the sacrificial material in the additional removed portion. However, the additional removed portion and the additional plug may be omitted.

Subsequently, a third sacrificial stacking portion 123s may be formed on the second sacrificial stacking portion 122s, a third channel through portion H3 may be formed in the cell array region, and a second preliminary through portion G2 may be formed in the connection region. Unless otherwise described, a description with reference to FIG. 12 may be applied.

The etching process of forming the second preliminary through portion G2 may be stopped in the second etch stopping pattern 1952s, and the etching process of forming the third channel through portion H3 may be stopped in the second plug 1262s and/or the additional plug. Accordingly, in the etching process of forming the second preliminary through portion G2 and/or the third channel through portion H3, the etching may be stably stopped in the second etch stopping pattern 1952s and/or the second plug 1262s.

Subsequently, a semiconductor device may be formed by performing processes with reference to FIG. 13 to FIG. 20. In a process of forming a third channel sacrificial portion 126c by filling a sacrificial material in a third channel through portion H3, the second plug 1262s may be removed after or in the process of removing the second channel sacrificial portion 126b.

In some implementations, in the etching process of forming the second channel through portion H2 and/or the third channel through portion H3, the etching may be stably stopped by a plug (e.g., the first plug 1261s and/or the second plug 1262s).

Hereinafter, referring to FIG. 25 to FIG. 28, semiconductor devices according to implementations will be described in more detail. To the extent that an element is not described in detail below, it may be understood that the element is at least similar to a corresponding element that has been described elsewhere within the present disclosure. A portion which is not described in the above will be described in detail.

FIG. 25 is a cross-sectional view illustrating an example of a portion of a semiconductor device. FIG. 25 illustrates a portion corresponding to FIG. 3.

Referring to FIG. 25, in some implementations, in a thickness direction of a semiconductor device (a Z-axis direction in the drawings), a first expanded part 1951c adjacent to a first boundary 121p and a second expanded parts 1952c adjacent to a second boundary 122p may have different lengths. In FIG. 25, it is illustrated as an example that a length of the first expanded part 1951c is less than a length of the second expanded part 1952c, but the implementations are not limited thereto. In some implementations, the length of the first expanded part 1951c may be greater than the length of the second expanded part 1952c. In some implementations, the first expanded part 1951c and the second expanded part 1952c may have different lengths, and design freedom may be improved.

FIG. 26 is a cross-sectional view illustrating an example of a portion of a semiconductor device. FIG. 26 illustrates a portion corresponding to FIG. 3.

Referring to FIG. 26, in some implementations, an expanded part 195c may be disposed at a part of a plurality of boundaries 120p, and may not disposed at the other of the plurality of boundaries 120p. That is, at least one of a plurality of connection contacts (e.g., one of a first connection contact 193 and a second connection contact 194) may not include a first shaped contact 195 having a first shape.

For example, as illustrated in FIG. 26, the first connection contact 193 may include the first shaped contact 195 having the first shape, and the second connection contact 194 may include a second shaped contact 196 having a second shape and may not include the first shaped contact 195. That is, the first connection contact 193 including a first expanded part 1951c adjacent to a first boundary 121p may be included, but a contact including a second expanded part adjacent to a second boundary 122p may not be included. The second connection contact 194 may include a connection part disposed in a second through portion formed by a plurality of partial etching processes using a binary system, and may not include portions corresponding to an extension part and an expanded part.

In some implementations, a second connection contact may include a first shaped contact 195 having a first shape, and a first connection contact may include a second shaped contact 196 having a second shape and may not include the first shaped contact 195. That is, a contact including a second expanded part adjacent to the second boundary 122p may be included, but a contact including a first expanded part adjacent to the first boundary 121p may not be included. The first connection contact may include a connection part disposed in a second through portion formed by a plurality of partial etching processes using a binary system, and may not include portions corresponding to an extension part and an expanded part.

In some implementations, a plurality of boundaries 120p may have three or more boundaries, an expanded part 195c may be provided in at least one of the three or more boundaries, and the expanded part 195c may not be provided in at least another one of the three or more boundaries. Other various modified implementations are possible.

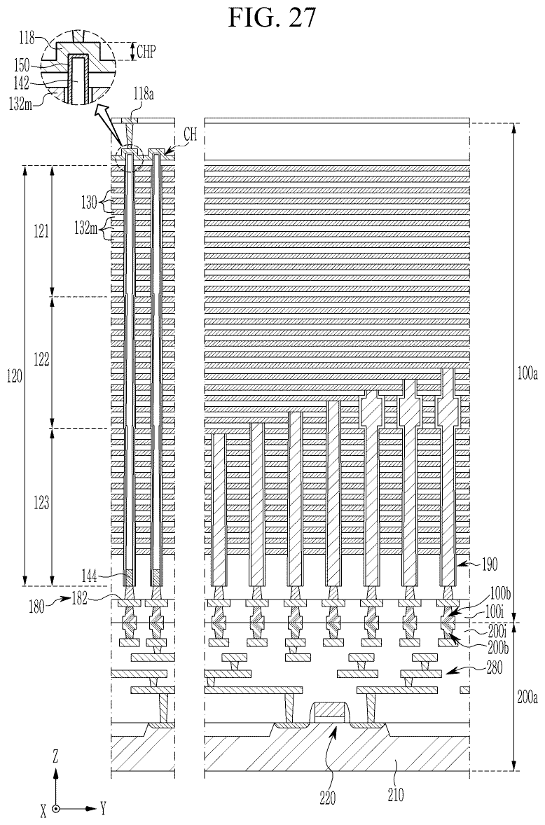

FIG. 27 is a partial cross-sectional view schematically illustrating an example of a semiconductor device.

Referring to FIG. 27, a semiconductor device may be formed by separately forming a cell region 100a and a circuit region 200a and boding the cell region 100a and the circuit region 200a. For example, the cell region 100a and the circuit region 200a may be bonded to each other by hybrid bonding including metal bonding and insulation-layer bonding. For example, the cell region 100a and the circuit region 200a may be bonded to each other by a chip to chip (C2C) bonding process, a chip-to-wafer bonding process, or a wafer-to-wafer bonding process.

The circuit region 200a may include a first substrate 210, a circuit element 220, a circuit wiring portion 280, and a bonding structure 200b that is electrically connected to the circuit wiring portion 280 and is disposed in a surface facing the cell region 100a. A region other than the bonding structure 200b in the surface facing the cell region 100a may be covered by a bonding insulation layer 200i.

The cell region 100a may include a gate stacking structure 120, a channel structure CH, a cell wiring portion 180, and a bonding structure 100b.

In some implementations, the gate stacking structure 120 may be sequentially stacked downward in FIG. 27, and may have a structure in which a gate stacking structure 120 illustrated in FIG. 1 is disposed in a vertically inverted manner. The channel structure CH passing through the gate stacking structure 120 may have a structure in which a channel structure CH illustrated in FIG. 2 is disposed in a vertically inverted manner. Accordingly, in a cross-sectional view, the channel structure CH may have an inclined side surface such that a width of the channel structure CH decreases far away from the circuit region 200a. A channel pad 144 and the cell wiring portion 180 on or above the gate stacking structure 120 may be adjacent to the circuit region 200a.

The cell wiring portion 180 may include a first wiring portion and a second wiring portion. The first wiring portion may be disposed on a first surface of the gate stacking structure 120 adjacent to the circuit region 200a. The second wiring portion may be disposed on a second surface of the gate stacking structure 120 opposite to the first surface of the gate stacking structure 120.

The first wiring portion may include a bit line 182 and a first wiring. The first wiring may be electrically connected to the bit line 182, a gate contact 190, an input/output connection wiring, or the like. The second wiring portion may include a horizontal conductive layer 118, and a second wiring 118a electrically connected to the horizontal conductive layer 118. The first wiring or the second wiring 118a may include one wiring layer or a plurality of wiring layers that are spaced apart from each other while interposing an insulation layer therebetween and are electrically connected by a contact via to form a desired path.

In some implementations, the channel structure CH may include a protrusion portion CHP protruding from a surface of the gate stacking structure 120 opposite to the first wiring portion. A gate dielectric layer 150 is not disposed in the protrusion portion CHP and a channel layer 140 disposed in the protrusion portion CHP may be exposed to an outside. The horizontal conductive layer 118 may be electrically connected to the channel layer 140 in the protrusion portion CHP. However, the implementations are not limited thereto, and horizontal conductive layers 112 and 114 illustrated in FIG. 1 may be included. Other various modified implementations are possible.

The horizontal conductive layer 118 may include a semiconductor layer including a semiconductor material. For example, the horizontal conductive layer 118 may include a semiconductor layer including or be formed or a single-crystalline or polycrystalline silicon, germanium, silicon-germanium, or the like.

The bonding structure 100b of the cell region 100a may include a first bonding structure. The first bonding structure may be electrically connected to the first wiring portion and be disposed on a surface facing the circuit region 200a. A region other than the bonding structure 100b (e.g., the first bonding structure) may be covered by a bonding insulation layer 100i (e.g., a first bonding insulation layer).

For example, the bonding structure 200b of the circuit region 200a and/or the bonding structure 100b of the cell region 100 may include aluminum, copper, tungsten, or an alloy including the same. For example, the bonding structure 200b of the cell region 200a and the bonding structure 100b of the cell region 100a may include copper such that the cell region 100a and the circuit region 200a may be bonded (e.g., directly bonded) to each other by copper-to-copper bonding.

In some implementations, the semiconductor device may include an input/output pad and an input/output connection wiring electrically connect to the input/output pad. The input/output connection wiring may be electrically connected to a part of bonding structures 100b of the cell region 100a. The input/output pad may pad may be disposed, for example, on an outer surface of the second wiring portion. In some implementations, an additional input/output pad electrically connected to the circuit region 200a may be provided.

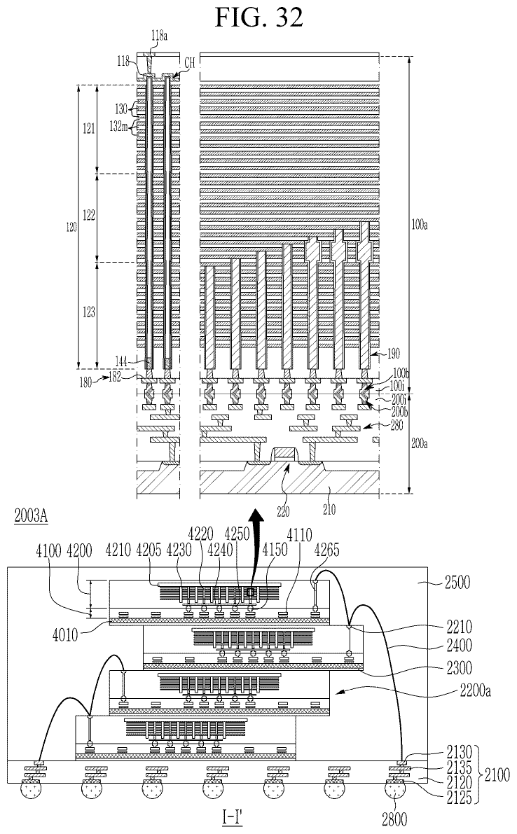

For example, the circuit region 200a and the cell region 100a may be portions corresponding to a first structure 1100F and a second structure 1100S of a semiconductor device 1100 included in an electronic system 1000 illustrated in FIG. 29, respectively. For example, the circuit region 200a and the cell region 100a may be regions including a first structure 4100 and a second structure 4200 of a semiconductor chip 2200a illustrated in FIG. 32, respectively.

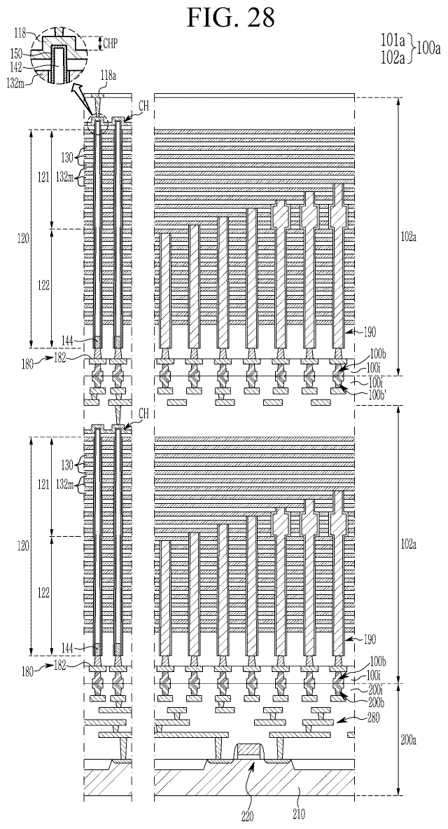

FIG. 28 is a partial cross-sectional view schematically illustrating an example of a semiconductor device.

Referring to FIG. 28, in a semiconductor device, a cell region 100a may include a plurality of cell regions (e.g., a first cell region 101a and a second cell region 102a). That is, the semiconductor device according to the modified implementation may have a multi bonding structure.

The first cell region 101a may include a gate stacking structure 120, a channel structure CH, a cell wiring portion 180, and a bonding structure 100b. Unless otherwise described, a description of a cell region 100a with reference to FIG. 27 may be applied to the first cell region 101a.

In the first cell region 101a, the bonding structure 100b may include a first bonding structure and a second bonding structure. The first bonding structure may be electrically connected to a first wiring portion and be disposed on a surface facing the circuit region 200a. The second bonding structure may be electrically connected to a second wiring portion and be disposed on a surface opposite to the circuit region 200a. A region other than the bonding structure 100b may be covered by a bonding insulation layer 100i. For example, the bonding insulation layer 100i may include a first bonding insulation layer in a region other than the first bonding structure, and a second bonding insulation layer in a region other than the second bonding structure.

The circuit region 200a and the first cell region 101a may be bonded to each other by hybrid bonding including metal bonding and insulation-layer bonding. For example, the bonding structure 200b of the circuit region 200a and the bonding structure 100b (e.g., the first bonding structure) of the first cell region 101a may be bonded to each other, and a bonding insulation layer 200i of the circuit region 200a and the bonding insulation layer 100i (e.g., the first bonding insulation layer) of the first cell region 101a may be bonded to each other.

The second cell region 102a may include a gate stacking structure 120, a channel structure CH, a cell wiring portion 180, and a bonding structure 100b. Unless otherwise described, a description of the cell region 100a with reference to FIG. 27 may be applied to the second cell region 102a.

The first cell region 101a and the second cell region 102a may be bonded to each other by hybrid bonding including metal bonding and insulation-layer bonding. For example, the bonding structure 100b (e.g., the second bonding structure) of the first cell region 101a and the bonding structure 100b (e.g., the first bonding structure) of the second cell region 102a may be bonded to each other, and the bonding insulation layer 100i (e.g., the second bonding insulation layer) of the first cell region 101a and the bonding insulation layer 100i (e.g., the first bonding insulation layer) of the second cell region 102a may be bonded to each other.

In FIG. 28, it is illustrated as an example that the plurality of cell regions include the first cell region 101a and the second cell region 102a. However, the implementations are not limited thereto, and the plurality of cell regions may include three or more cell regions.

In FIG. 28, it is illustrated as an example that the cell region 100a includes the plurality of cell regions (e.g., the first cell region 101a and the second cell region 102a) in a semiconductor device illustrated in FIG. 27. However, the implementations are not limited thereto, and a cell region 100a may include a plurality of cell regions (e.g., a first cell region 101a and a second cell region 102a) in a semiconductor device illustrated in FIG. 1. In this instance, the second cell region 102a may be disposed on or above the first cell region 101a.

In FIG. 28, it is illustrated as an example that the cell region 100a includes the plurality of cell regions (e.g., the first cell region 101a and the second cell region 102a) in a semiconductor device illustrated in FIG. 27. However, the implementations are not limited thereto, and the circuit region 200a may include a plurality of circuit regions stacked on each other. Other various modified implementations are possible.

In FIG. 28, it is illustrated as an example that an upper portion of each of the plurality of cell regions (e.g., the first cell region 101a and the second cell region 102a) faces the circuit region 200a. However, the implementations are not limited thereto. In some implementations, an upper portion of at least one of the plurality of cell regions may be far away from or opposite to the circuit region 200a. That is, in at least one of the plurality of cell regions, the gate stacking structure 120 may have a structure illustrated in FIG. 1, or the channel structure CH have a structure illustrated in FIG. 2. Thereby, in the plurality of cell regions, the channel structure CH may have an inclined side surface in a cross-sectional view such that a width decreases toward the circuit region 200a, or a channel pad 144 may be far away from or opposite to the circuit region 200a.

In FIG. 28, it is illustrated as an example that, in each of the plurality of cell regions (e.g., the first cell region 101a or the second cell region 102a), the plurality of gate stacking portions include the first gate stacking portion 121 and the second gate stacking portion 122. In this instance, the first gate stacking portion 121 may be a first stacking portion, and the second gate stacking portion 122 may be a second stacking portion. However, the implementations are not limited thereto, and the first stacking portion may include two or more gate stacking portions. An example of an electronic system including a semiconductor device will be described in detail below.

FIG. 29 schematically illustrates an electronic system including an example of a semiconductor device.

Referring to FIG. 29, an electronic system 1000 may include a semiconductor device 1100 and a controller 1200 that is electrically connected to the semiconductor device 1100. The electronic system 1000 may be a storage device that includes one or a plurality of semiconductor devices 1100 or an electronic device that includes the storage device. For example, the electronic system 1000 may be a solid-state drive (SSD) device, a universal serial bus (USB), a computing system, a medical device, or a communication device that includes one or a plurality of semiconductor devices 1100.

The semiconductor device 1100 may be a non-volatile memory device, and for example, may be a NAND flash memory device described with reference to FIG. 1 to FIG. 28. The semiconductor device 1100 may include a first structure 1100F and a second structure 1100S that is disposed on the first structure 1100F. In some implementations, the first structure 1100F may be disposed next to the second structure 1100S. The first structure 1100F may be a peripheral circuit structure that includes a decoder circuit 1110, a page buffer 1120, and a logic circuit 1130. The second structure 1100S may be a memory cell structure that includes a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of memory cell strings CSTR may include lower transistors LT1 and LT2 that are adjacent to the common source line CSL, upper transistors UT1 and UT2 that are adjacent to the bit line BL, and a plurality of memory cell transistors MCT between the lower transistors LT1 and LT2 and the upper transistors UT1 and UT2. A number of the lower transistors LT1 and LT2 and a number of the upper transistors UT1 and UT2 may be variously modified.

In some implementations, the lower transistor LT1 or LT2 may include a ground selection transistor, and the upper transistor UT1 or UT2 may include a string selection transistor. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 that extends to the second structure 1100S within the first structure 1100F. The bit line BL may be electrically connected to the page buffer 1120 through a second connection wiring 1125 that extends to the second structure 1100S within the first structure 1100F.

In the first structure 1100F, the decoder circuit 1110 and the page buffer 1120 may execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 that is electrically connected to the logic circuit 1130. The input/output pad 1101 may be electrically connected to the logic circuit 1130 through an input/output connection wiring 1135 that extends to the second structure 1100S within the first structure 1100F.

The controller 1200 may include a processor 1210, a NAND controller 1220, and a host interface 1230. In some implementations, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or the like may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

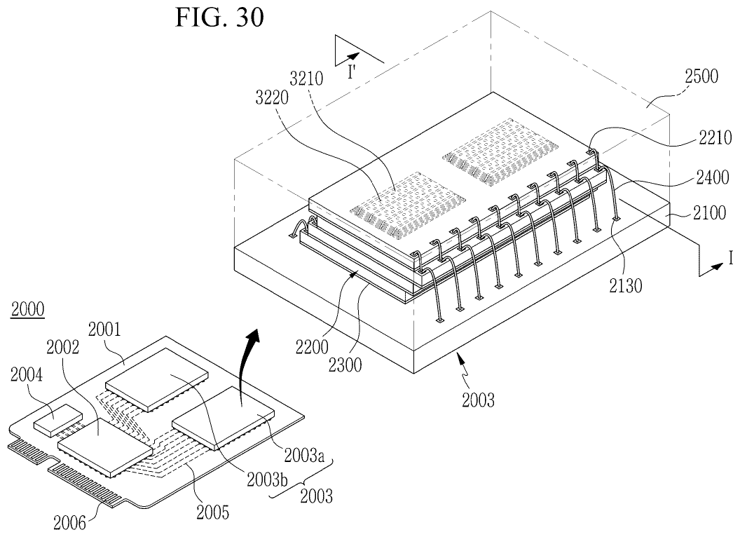

FIG. 30 is a perspective view schematically illustrating an example of an electronic system including a semiconductor device.

Referring to FIG. 30, an electronic system 2000 may include a main substrate 2001, a controller 2002 that is mounted on the main substrate 2001, one or more semiconductor packages 2003, and a DRAM 2004. The semiconductor package 2003 and the DRAM 2004 may be connected to the controller 2002 through a wiring pattern 2005 that is provided on the main substrate 2001.

The main substrate 2001 may include a connector 2006 that includes a plurality of pins coupled to the external host. A number and an arrangement of the plurality of pins in the connector 2006 may vary depending on a communication interface between the electronic system 2000 and the external host. In some implementations, the electronic system 2000 may communicate with the external host according to any one of interfaces such as a universal serial bus (USB), a peripheral component interconnect express (PCI-Express), a serial advanced technology attachment (SATA), or an M-Phy for a universal flash storage (UFS). In some implementations, the electronic system 2000 may operate by power that is supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003, and may improve an operating speed of the electronic system 2000.

The DRAM 2004 may be a buffer memory for mitigating or buffering a speed difference between the semiconductor package 2003, which is a data storage space, and the external host. The DRAM 2004 that is included in the electronic system 2000 may also be a kind of cache memory, and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b that are spaced apart from each other. Each of the first and second semiconductor packages 2003a and 2003b may be a semiconductor package that includes a plurality of semiconductor chips 2200. Each of the first and second semiconductor packages 2003a and 2003b may include a package substrate 2100, a semiconductor chip 2200 that is disposed on the package substrate 2100, an adhesive layer 2300 at a lower surface of each semiconductor chip 2200, a connection structure 2400 that electrically connects the semiconductor chip 2200 and the package substrate 2100, and a molding layer 2500 that covers the semiconductor chip 2200 and the connection structure 2400 on the package substrate 2100.

The package substrate 2100 may be a printed circuit board that includes a package upper pad 2130. Each semiconductor chip 2200 may include an input/output pad 2210. The input/output pad 2210 may correspond to an input/output pad 1101 of FIG. 29. Each semiconductor chip 2200 may include a gate stacking structure 3210 and a channel structure 3220. The semiconductor chip 2200 may include a semiconductor device described with reference to FIG. 1 to FIG. 28.

In some implementations, the connection structure 2400 may be a bonding wire that electrically connects the input/output pad 2210 and the package upper pad 2130. Accordingly, in each of the first and second semiconductor packages 2003a and 2003b, the semiconductor chips 2200 may be electrically connected to each other using a bonding wire type, and the semiconductor chip 2200 may be electrically connected to the package upper pad 2130 of the package substrate 2100 using a bonding wire type. In some implementations, in each of the first and second semiconductor packages 2003a and 2003b, the semiconductor chips 2200 may be electrically connected to each other by a connection structure that includes a through silicon via (TSV) instead of the connection structure 2400 of the bonding wire type.

In some implementations, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to each other by a wiring of the interposer substrate.

FIG. 31 and FIG. 32 are cross-sectional views schematically illustrating example semiconductor packages, respectively. FIG. 31 and FIG. 32 respectively illustrate implementations of the semiconductor package 2003 of FIG. 30, and conceptually illustrate a region obtained by cutting the semiconductor package 2003 of FIG. 30 along a line I-I′.

Referring to FIG. 31, in a semiconductor package 2003, the package substrate 2100 may be a printed circuit board. The package substrate 2100 may include a package substrate body portion 2120, a package upper pad 2130 at an upper surface of the package substrate body portion 2120, a package lower pad 2125 disposed at a lower surface of the package substrate body portion 2120 or exposed through the lower surface of the package substrate body portion 2120, and an internal wiring 2135 electrically connecting the package upper pad 2130 and the package lower pad 2125 inside the package substrate body portion 2120. The package upper pad 2130 may be electrically connected to the connection structure 2400. The package lower pad 2125 may be connected to a wiring pattern 2005 of the main substrate 2001 of the electronic system 2000 illustrated in FIG. 30 through a conductive connection portion 2800.

The semiconductor chip 2200 may include a semiconductor substrate 3010, and a first structure 3100 and a second structure 3200 sequentially stacked on the semiconductor substrate 3010. The first structure 3100 may include a peripheral circuit region including a peripheral wiring 3110. The second structure 3200 may include a common source line 3205, a gate stacking structure 3210 on the common source line 3205, a channel structure 3220 and a separation structure 3230 passing through the gate stacking structure 3210, a bit line 3240 electrically connected to the channel structure 3220, and a gate connection wiring electrically connected to a word line WL (refer to FIG. 29) of the gate stacking structure 3210.

In the semiconductor chip 2200 or the semiconductor device, a gate contact may include an expanded part that is between an extension part in a first through portion and a connection part in a second through portion. The expanded part may protrude in a horizontal direction and be a portion where an etch stopping pattern was disposed. Accordingly, etching may be stably stopped by the etch stopping pattern in a first etching process of forming the first through portion, and a number of a plurality of partial etching processes using a binary system in a second etching process of forming the second through portion may be reduced. As a result, a manufacturing process may be simplified.

Each of the semiconductor chips 2200 may include a through wiring 3245 that is electrically connected to the peripheral wiring 3110 of the first structure 3100 and extends into the second structure 3200. The through wiring 3245 may penetrate the gate stacking structure 3210, and may be further provided at an outside of the gate stacking structure 3210. Each semiconductor chip 2200 may further include an input/output connection wiring 3265 electrically connected to the peripheral wiring 3110 of the first structure 3100 and extending into the second structure 3200, and an input/output pad 2210 electrically connected to the input/output connection wiring 3265.

In some implementations, in the semiconductor package 2003, a plurality of semiconductor chips 2200 may be electrically connected to each other by a connection structure 2400 having a bonding wire type. In some implementations, the plurality of semiconductor chips 2200 or a plurality of portions constituting the plurality of semiconductor chips 2200 may be electrically connected by a connection structure including a through silicon via (TSV).

Referring to FIG. 32, in a semiconductor package 2003A, each semiconductor chip 2200a may include a semiconductor substrate 4010, a first structure 4100 on the semiconductor substrate 4010, and a second structure 4200 disposed on the first structure 4100 and bonded to the first structure 4100 by a wafer bonding type.

The first structure 4100 may include a peripheral circuit region including a peripheral wiring 4110 and a first bonding structure 4150. The second structure 4200 may include a common source line 4205, a gate stacking structure 4210 between the common source line 4205 and the first structure 4100, a channel structure 4220 and a separation structure 4230 penetrating the gate stacking structure 4210, and a second bonding structure 4250 electrically connected to the channel structure 4220 and a word line WL (refer to FIG. 29) of the gate stacking structure 4210. For example, the second bonding structure 4250 may be electrically connected to the channel structure 4220 and the word line WL through a bit line 4240 electrically connected to the channel structure 4220 and a gate connection wiring electrically connected to the word line WL. The first bonding structure 4150 of the first structure 4100 and the second bonding structure 4250 of the second structure 4200 may be in contact with and bonded to each other. For example, portions of the first bonding structure 4150 and the second bonding structure 4250 where the first bonding structure 4150 and the second bonding structure 4250 are bonded may include copper (Cu).

In the semiconductor chip 2200a or the semiconductor device, a gate contact may include an expanded part that is between an extension part in a first through portion and a connection part in a second through portion. The expanded part may protrude in a horizontal direction and be a portion where an etch stopping pattern was disposed. Accordingly, etching may be stably stopped by the etch stopping pattern in a first etching process of forming the first through portion, and a number of a plurality of partial etching processes using a binary system in a second etching process of forming the second through portion may be reduced. As a result, a manufacturing process may be simplified.

Each of the semiconductor chips 2200a may further include an input/output pad 2210 and an input/output connection wiring 4265 at a lower portion of the input/output pad 2210. The input/output connection wiring 4265 may be electrically connected to a part of the second bonding structures 4250.

In some implementations, in the semiconductor package 2003A, a plurality of semiconductor chips 2200a may be electrically connected to each other by the connection structure 2400 having a bonding wire type. In some implementations, the plurality of semiconductor chips 2200a or a plurality of portions constituting the plurality of semiconductor chips 2200a may be electrically connected by a connection structure including a through silicon via (TSV).

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While some examples have been described in connection with what is presently considered to be some implementations, it is to be understood that the disclosure is not limited to the disclosed implementations, and that the disclosure is intended to cover various modifications and equivalent arrangements included within the spirit and scope of the appended claims.

What is claimed is:

1. A semiconductor device comprising:
a gate stacking structure including a plurality of interlayer insulation layers and a plurality of gate electrodes that are alternately stacked on each other;
a channel structure extending through the gate stacking structure; and
a plurality of gate contacts, wherein each gate contact of the plurality of gate contacts passes through a portion of the gate stacking structure, and is electrically connected to a respective gate electrode of the plurality of gate electrodes,
wherein the gate stacking structure includes a first stacking portion and a second stacking portion on the first stacking portion,
wherein the first stacking portion includes at least one gate stacking portion,
wherein the plurality of gate contacts include a plurality of first contacts and a plurality of second contacts,
wherein the plurality of first contacts are electrically connected to a plurality of first electrodes, respectively, the plurality of first electrodes being included in the first stacking portion,
wherein the plurality of second contacts are electrically connected to a plurality of second electrodes, respectively, the plurality of second electrodes being included in the second stacking portion,
wherein the plurality of first contacts include a first shaped contact having a first shape,
wherein the first shaped contact includes an extension part, a connection part, and an expanded part, the extension part passing through at least the second stacking portion, the connection part passing through a portion of the first stacking portion and electrically connected to a respective first electrode of the plurality of first electrodes, the expanded part being between the extension part and the connection part, and the expanded part being adjacent to a boundary of the at least one gate stacking portion, and
wherein the expanded part protrudes from the connection part in a horizontal direction.

2. The semiconductor device of claim 1, wherein the expanded part protrudes from the extension part in the horizontal direction.

3. The semiconductor device of claim 1, wherein the expanded part passes through at least two gate electrodes of the plurality of gate electrodes or at least two interlayer insulation layers of the plurality of interlayer insulation layers.

4. The semiconductor device of claim 3, wherein the expanded part passes through two gate electrodes to twenty gate electrodes of the plurality of gate electrodes or two interlayer insulation layers to twenty interlayer insulation layers of the plurality of interlayer insulation layers.

5. The semiconductor device of claim 1, wherein the connection part has an inclined side surface such that a width of the connection part decreases in a direction away from the expanded part, or the extension part includes an extension portion having an inclined side surface such that a width of the extension portion decreases in a direction toward the expanded part, and
wherein a step is between the connection part and the expanded part or between the extension part and the expanded part.

6. The semiconductor device of claim 1, wherein
a ratio of a width of the expanded part to a width of the connection part in a portion where the expanded part and the connection part are adjacent to each other is greater than or equal to 1.1, or
a ratio of the width of the expanded part to a width of the extension part in a portion where the expanded part and the extension part are adjacent to each other is greater than or equal to 1.1.

7. The semiconductor device of claim 1, wherein a width of the expanded part is greater than a width of an upper portion of at least one gate contact of the plurality of gate contacts adjacent to an upper portion of the gate stacking structure.

8. The semiconductor device of claim 1, wherein the first shaped contact includes a plurality of first shaped contacts, and
wherein a plurality of extension parts in the plurality of first shaped contacts have a same length, a plurality of expanded parts in the plurality of first shaped contacts have a same length, and a plurality of connection parts in the plurality of first shaped contacts have different lengths.

9. The semiconductor device of claim 1, wherein a second contact includes an additional connection part passing through a portion of the second stacking portion, the additional connection part being electrically connected to a respective second electrode of the plurality of second electrodes, the second contact having a second shape different from the first shape.

10. The semiconductor device of claim 1, wherein the plurality of first contacts include a second shaped contact having a shape different from the first shape.

11. The semiconductor device of claim 10, wherein the second shaped contact includes an additional connection part passing through the second stacking portion and the portion of the first stacking portion, the second shaped contact being electrically connected to a respective first electrode of the plurality of first electrodes that overlaps or corresponds to the expanded part of the first shaped contact.

12. The semiconductor device of claim 1, wherein the first stacking portion includes a plurality of gate stacking portions that are sequentially stacked,
wherein the first shaped contact includes a plurality of first shaped contacts, and
wherein the plurality of first shaped contacts include a plurality of expanded parts, the plurality of expanded parts being adjacent to a plurality of boundaries at a plurality of upper portions of the plurality of gate stacking portions, respectively.

13. The semiconductor device of claim 12, wherein the plurality of boundaries include a first boundary and a second boundary,
wherein the plurality of first shaped contacts include a first connection contact and a second connection contact,
wherein the first connection contact includes a first expanded part adjacent to the first boundary,
wherein the second connection contact includes a second expanded part adjacent to the second boundary, and
wherein the first expanded part and the second expanded part have a same length in a thickness direction of the semiconductor device.

14. The semiconductor device of claim 12, wherein the plurality of boundaries include a first boundary and a second boundary,
wherein the plurality of first shaped contacts include a first connection contact and a second connection contact,
wherein the first connection contact includes a first expanded part adjacent to the first boundary,
wherein the second connection contact includes a second expanded part adjacent to the second boundary, and
wherein the first expanded part and the second expanded part have different lengths in a thickness direction of the semiconductor device.

15. The semiconductor device of claim 1, wherein the first stacking portion includes a plurality of gate stacking portions that are sequentially stacked,
wherein the boundary includes a plurality of upper boundaries at a plurality of upper portions of the plurality of gate stacking portions, respectively, and
wherein the expanded part of the first shaped contact is adjacent to at least one upper boundary of the plurality of upper boundaries.

16. A semiconductor device comprising:
a gate stacking structure including a plurality of interlayer insulation layers and a plurality of gate electrodes that are alternately stacked on each other;
a channel structure extending through the gate stacking structure; and
a plurality of gate contacts, wherein each gate contact of the plurality of gate contacts passes through a portion of the gate stacking structure and is electrically connected to a respective gate electrode of the plurality of gate electrodes,
wherein the gate stacking structure includes a first stacking portion and a second stacking portion on the first stacking portion,
wherein the plurality of gate contacts include a plurality of first contacts and a plurality of second contacts,
wherein the plurality of first contacts are electrically connected to a plurality of first electrodes, respectively, the plurality of first electrodes being included in the first stacking portion,
wherein the plurality of second contacts are electrically connected to a plurality of second electrodes, respectively, the plurality of second electrodes being included in the second stacking portion,
wherein the plurality of first contacts include a first shaped contact having a first shape,
wherein the first shaped contact includes an extension part passing through at least the second stacking portion, a connection part passing through a portion of the first stacking portion and electrically connected to a respective first electrode of the plurality of first electrodes, and an expanded part passing through at least two gate electrodes of the plurality of gate electrodes or at least two interlayer insulation layers of the plurality of interlayer insulation layers, and
wherein the expanded part protrudes from the connection part in a horizontal direction.

17. The semiconductor device of claim 16, wherein the first shaped contact includes a plurality of first shaped contacts, and
wherein a plurality of extension parts in the plurality of first shaped contacts have a same length, a plurality of expanded parts in the plurality of first shaped contacts have a same length, and a plurality of connection parts in the plurality of first shaped contacts have different lengths.

18. The semiconductor device of claim 16, wherein a second contact includes an additional connection part passing through a portion of the second stacking portion and electrically connected to a respective second electrode of the plurality of second electrodes, the second contact having a second shape different from the first shape.

19. The semiconductor device of claim 16, wherein the plurality of first contacts include a second shaped contact having a shape different from the first shape.

20. An electronic system comprising:
a main substrate;
a semiconductor device on the main substrate; and
a controller electrically connected to the semiconductor device on the main substrate,
wherein the semiconductor device includes:
a gate stacking structure including a plurality of interlayer insulation layers and a plurality of gate electrodes that are alternately stacked on each other;
a channel structure extending through the gate stacking structure; and
a plurality of gate contacts, wherein each gate contact of the plurality of gate contacts passes through a portion of the gate stacking structure and is electrically connected to a respective gate electrode of the plurality of gate electrodes,
wherein the gate stacking structure includes a first stacking portion and a second stacking portion on the first stacking portion,
wherein the first stacking portion includes at least one gate stacking portion,
wherein the plurality of gate contacts include a plurality of first contacts and a plurality of second contacts,
wherein the plurality of first contacts are electrically connected to a plurality of first electrodes, respectively, the plurality of first electrodes being included in the first stacking portion,
wherein the plurality of second contacts are electrically connected to a plurality of second electrodes, respectively, the plurality of second electrodes being included in the second stacking portion,
wherein the plurality of first contacts include a first shaped contact having a first shape,
wherein the first shaped contact includes an extension part passing through at least the second stacking portion, a connection part passing through a portion of the first stacking portion and electrically connected to a respective first electrode of the plurality of first electrodes, an expanded part between the extension part and the connection part, and the expanded part being adjacent to a boundary of the at least one gate stacking portion, and
wherein the expanded part protrudes from the connection part in a horizontal direction.
